(19) United States
(12) Patent Application Publication
(10) Pub. No.: US 2026/0196800 A1
(43) Pub. Date: Jul. 9, 2026

(54) LIGHT-EMITTING DEVICE AND LASER PROJECTION APPARATUS

(71) Applicant: Hisense Laser Display Co., Ltd, Qingdao City (CN)

(72) Inventors: Chongyao DUAN, Qingdao City (CN); Zinan ZHOU, Qingdao City (CN); Minglong ZHANG, Qingdao City (CN); Xu HAN, Qingdao City (CN); Youliang TIAN, Qingdao City (CN); Zhaoshi GUO, Qingdao City (CN)

(73) Assignee: Hisense Laser Display Co., Ltd, Qingdao City (CN)

(21) Appl. No.: 19/553,526

(22) Filed: Mar. 2, 2026

Related U.S. Application Data
(63) Continuation of application No. PCT/CN2024/136111, filed on Dec. 2, 2024.

(30) Foreign Application Priority Data
Dec. 8, 2023 (CN) 202311683844.6
Jan. 22, 2024 (CN) 202410089831.4

(51) Int. Cl. H01S 5/02315; H01S 5/02345; H01S 5/40; H04N 9/31

(52) U.S. Cl. CPC H01S 5/02315; H01S 5/02345; H01S 5/4093; H04N 9/3161

(57) ABSTRACT

A light-emitting device and a laser projection device. The light-emitting device includes a substrate and a light-emitting assembly. The substrate includes a substrate body, at least one connection pattern, a plurality of interconnection regions, and a plurality of groups of first pads. The light-emitting assembly is disposed on the at least one connection pattern and includes at least one package, a conductive structure, and a plurality of types of laser chips. At least one of a side wall and bottom wall of the at least one package is provided with connection wires. The plurality of types of laser chips are disposed in the at least one package and electrically connected to the connection wires. The plurality of types of laser chips are configured to emit at least two laser beams of different colors.

### CROSS-REFERENCE TO RELATED APPLICATIONS

This application is a continuation application of International Patent Application No. PCT/CN2024/136111, filed on Dec. 2, 2024, which claims priority to Chinese Patent Application No. 202311683844.6, filed on Dec. 8, 2023; and Chinese Patent Application No. 202410089831.4, filed on Jan. 22, 2024, which are incorporated herein by reference in their entireties.

### TECHNICAL FIELD

The present disclosure relates to the field of laser projection technologies, and in particular, to a laser device and a laser projection apparatus.

### BACKGROUND

With the improvement of living standards, demand for television products with high color saturation and high brightness has increased year by year, and advantages of laser projection apparatuses have become fully evident. In recent years, portable laser projection apparatuses are gained great popularity in the market, and miniaturized laser projection apparatuses have emerged as a natural result.

### SUMMARY

In an aspect, a light-emitting device is provided. The light-emitting device includes a substrate and a light-emitting assembly. The substrate includes a substrate body, at least one connection pattern, a plurality of interconnection regions, and a plurality of groups of first pads. The at least one connection pattern is disposed on the substrate body and includes a conductive portion. The plurality of interconnection regions are disposed on the substrate body. The plurality of groups of first pads are disposed on the substrate body. The plurality of groups of first pads are electrically connected to the conductive portion through the plurality of interconnection regions. Any one group of the plurality of groups of first pads includes two first pads with different polarities. The light-emitting assembly is disposed on the at least one connection pattern and includes: at least one package, a conductive structure, a plurality of types of laser chips. At least one of a side wall and bottom wall of the at least one package is provided with connection wires. The conductive structure is disposed on a side of the at least one package facing the substrate and electrically connected to the connection wires and the conductive portion. The plurality of types of laser chips are disposed in the at least one package and electrically connected to the connection wires. The plurality of types of laser chips are configured to emit at least two types of laser beams of different colors. Laser chips of a same type of the plurality of types of laser chips are electrically connected to the any one group of first pads.

In another aspect, a laser projection apparatus is provided. The laser projection apparatus includes a laser source assembly, a light modulation assembly, and a projection lens. The laser source assembly is configured to emit illumination beams, and the laser source assembly includes the light-emitting device described above. The light modulation assembly is configured to modulate the illumination beams provided by the laser source assembly, so as to obtain projection beams. The projection lens is configured to project the projection beams into an image.

### BRIEF DESCRIPTION OF THE DRAWINGS

In order to describe technical solutions in the present disclosure more clearly, the accompanying drawings to be used in some embodiments of the present disclosure or in the description in the related art will be introduced briefly. However, the accompanying drawings to be described below are merely accompanying drawings of some embodiments of the present disclosure, and a person of ordinary skill in the art may obtain other accompanying drawings according to those accompanying drawings.

FIG. 1 is a diagram showing a structure of a laser projection apparatus, in accordance with some embodiments;

FIG. 2 is a diagram showing a beam path of a laser source assembly, a light modulation assembly, and a projection lens in a laser projection apparatus, in accordance with some embodiments;

FIG. 3 is a diagram showing a principle of projection imaging by a laser projection apparatus, in accordance with some embodiments;

FIG. 4 is a schematic diagram showing operation of micromirrors, in accordance with some embodiments;

FIG. 5 is a diagram showing a structure of a light-emitting device in the related art;

FIG. 6 is an exploded view of a light-emitting device in the related art;

FIG. 7 is a diagram showing a structure of a light-emitting device, in accordance with some embodiments;

FIG. 8 is a diagram showing another structure of a light-emitting device, in accordance with some embodiments;

FIG. 9 is a diagram showing yet another structure of a light-emitting device, in accordance with some embodiments;

FIG. 10 is a diagram showing a structure of a cover plate and a plurality of first sealing portions, in accordance with some embodiments;

FIG. 11 is a diagram showing another structure of a cover plate and a plurality of first sealing portions, in accordance with some embodiments;

FIG. 12 is a diagram showing yet another structure of a cover plate and a plurality of first sealing portions, in accordance with some embodiments;

FIG. 13 is a diagram showing a structure of an accommodating structure, in accordance with some embodiments;

FIG. 14 is a diagram showing a structure of a plurality of accommodating structures, in accordance with some embodiments;

FIG. 15 is an exploded view of a light-emitting assembly, in accordance with some embodiments;

FIG. 16 is a diagram showing yet another structure of a light-emitting device, in accordance with some embodiments;

FIG. 17 is a diagram showing an operating principle of a light-emitting device in the related art;

FIG. 18 is a circuit diagram of a plurality of laser chips with a common anode wiring mode in the related art;

FIG. 19 is a circuit diagram of a plurality of laser chips with a common cathode wiring mode in the related art;

FIG. 20 is a diagram showing yet another structure of a light-emitting device, in accordance with some embodiments;

FIG. 21 is a diagram showing a structure of a substrate, in accordance with some embodiments;

FIG. 22 is a diagram showing another structure of a substrate, in accordance with some embodiments;

FIG. 23 is a block diagram of a light-emitting device, in accordance with some embodiments;

FIG. 24 is a bottom view of a package, in accordance with some embodiments;

FIG. 25 is a circuit diagram of a light-emitting device, in accordance with some embodiments;

FIG. 26 is a diagram showing yet another structure of a light-emitting device, in accordance with some embodiments;

FIG. 27 is a circuit diagram of a temperature-measuring component, in accordance with some embodiments;

FIG. 28 is a diagram showing yet another structure of a substrate, in accordance with some embodiments;

FIG. 29 is a diagram showing yet another structure of a substrate, in accordance with some embodiments;

FIG. 30 is a diagram showing yet another structure of a substrate, in accordance with some embodiments;

FIG. 31 is a circuit diagram of a package, in accordance with some embodiments;

FIG. 32 is a diagram showing yet another structure of a light-emitting device, in accordance with some embodiments;

FIG. 33 is a diagram showing a structure of wiring in a first package, in accordance with some embodiments;

FIG. 34 is a top view of wiring in a first package, in accordance with some embodiments;

FIG. 35 is a diagram showing yet another structure of a light-emitting device, in accordance with some embodiments;

FIG. 36 is a diagram showing a structure of wiring in a second package, in accordance with some embodiments;

FIG. 37 is a top view of wiring in a second package, in accordance with some embodiments;

FIG. 38 is a diagram showing yet another structure of a light-emitting device, in accordance with some embodiments;

FIG. 39 is a diagram showing a structure of a plurality of packages, in accordance with some embodiments;

FIG. 40 is a diagram showing yet another structure of a substrate, in accordance with some embodiments;

FIG. 41 is a diagram showing yet another structure of a light-emitting device, in accordance with some embodiments;

FIG. 42 is a bottom view of another package, in accordance with some embodiments;

FIG. 43 is a diagram showing a structure of a light-emitting assembly, in accordance with some embodiments;

FIG. 44 is a diagram showing yet another structure of a substrate, in accordance with some embodiments;

FIG. 45 is a top view of wiring in a package, in accordance with some embodiments;

FIG. 46 is a diagram showing yet another structure of a light-emitting device, in accordance with some embodiments;

FIG. 47 is a bottom view of yet another package, in accordance with some embodiments;

FIG. 48A is a flow chart of a manufacturing method of a light-emitting device, in accordance with some embodiments;

FIG. 48B is another flow chart of a manufacturing method of a light-emitting device, in accordance with some embodiments;

FIG. 49 is yet another flow chart of a manufacturing method of a light-emitting device, in accordance with some embodiments;

FIG. 50 is yet another flow chart of a manufacturing method of a light-emitting device, in accordance with some embodiments;

FIG. 51 is a diagram showing a structure of a cover plate and a second sealing portion, in accordance with some embodiments;

FIG. 52 is a diagram showing a structure of a cover plate, a plurality of first sealing portions and a second sealing portion, in accordance with some embodiments;

FIG. 53 is a diagram showing another structure of a light-emitting assembly, in accordance with some embodiments;

FIG. 54 is a diagram showing yet another structure of a light-emitting device, in accordance with some embodiments; and

FIG. 55 is a diagram showing a structure of cover plates, in accordance with some embodiments.

### DETAILED DESCRIPTION

Some embodiments of the present disclosure will be clearly and completely described below with reference to the accompanying drawings. However, the described embodiments are merely some but not all embodiments of the present disclosure. All other embodiments obtained by a person of ordinary skill in the art based on embodiments provided in the present disclosure will be included in the protection scope of the present disclosure.

Unless the context requires otherwise, throughout the description and the claim, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the terms described above do not necessarily refer to the same embodiment(s) or example(s). In addition, the specific features, structures, materials, or characteristics may be included in any one or more embodiments or examples in any suitable manner.

Hereinafter, the terms such as “first” and “second” are used for descriptive purposes only and are not to be construed as indicating or implying the relative importance or implicitly indicating the number of indicated technical features. Thus, features defined by “first” or “second” may explicitly or implicitly include one or more of the features. In the description of some embodiments of the present disclosure, the term “a plurality of” or “the plurality of” means two or more unless otherwise specified.

In the description of some embodiments, the term “connected” and derivatives thereof may be used. The term “connected” will be understood in a broad sense. For example, the term “connected” may represent a fixed connection, a detachable connection, or a one-piece connection, or may represent a direct connection, or may represent an indirect connection through an intermediate medium. The embodiments disclosed herein are not necessarily limited to the content herein.

The phrase “at least one of A, B, and C” has the same meaning as the phrase “at least one of A, B, or C,” both including the following combinations of A, B, and C: only A, only B, only C, a combination of A and B, a combination of A and C, a combination of B and C, and a combination of A, B, and C.

As used herein, the term “if” is, optionally, construed as “when” or “in a case where” or “in response to determining that” or “in response to detecting,” depending on the context. Similarly, depending on the context, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event].”

The use of the phrase “applicable to” or “configured to” herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or value exceeding those stated.

The terms such as “about,” “substantially,” and “approximately” as used herein include a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system).

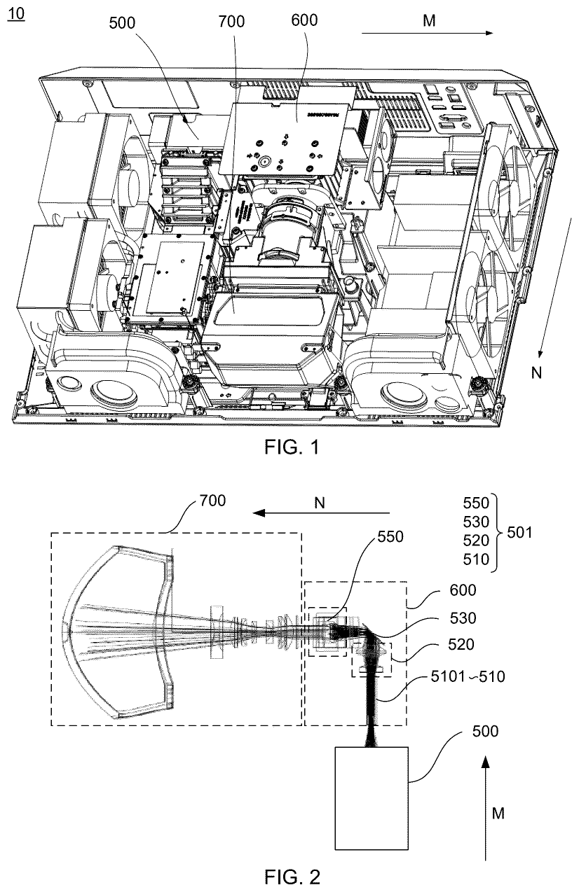

FIG. 1 is a diagram showing a structure of a laser projection apparatus, in accordance with some embodiments.

A laser projection apparatus 10 is provided in some embodiments of the present disclosure. As shown in FIG. 1, the laser projection apparatus 10 includes a laser source assembly 500, a light modulation assembly 600, and a projection lens 700. The laser source assembly 500 is configured to provide illumination beams. The light modulation assembly 600 is configured to modulate the illumination beams provided by the laser source assembly 500 with image signals, so as to obtain projection beams. The projection lens 700 is configured to project the projection beams into an image on a screen or a wall.

The laser source assembly 500, the light modulation assembly 600, and the projection lens 700 are sequentially connected in a propagation direction of beams, and each is wrapped by a corresponding housing. The housings of the laser source assembly 500, the light modulation assembly 600, and the projection lens 700 each support their corresponding optical components, and make the optical components satisfy preset sealing or airtight requirements.

As shown in FIG. 1, a first end of the light modulation assembly 600 is connected to the laser source assembly 500, and the laser source assembly 500 and the light modulation assembly 600 are arranged in an exit direction (referring to the direction M shown in FIG. 1) of the illumination beams of the laser projection apparatus 10. A second end of the light modulation assembly 600 is connected to the projection lens 700, and the light modulation assembly 600 and the projection lens 700 are arranged in an exit direction (referring to the direction N shown in FIG. 1) of the projection beams of the laser projection apparatus 10. The direction M is substantially perpendicular to the direction N. In one aspect, such connection structure may adapt to characteristics of a beam path of a reflective light valve in the light modulation assembly 600, and in another aspect, it is also conducive to shortening a length of a beam path in a one-dimensional direction, which is helpful for structural arrangement of the laser projection apparatus 10.

For example, in a case where the laser source assembly 500, the light modulation assembly 600, and the projection lens 700 are disposed in a one-dimensional direction (e.g., the direction M), the length of the beam path in the one-dimensional direction is long, which is not conducive to the structural arrangement of the laser projection apparatus 10.

In some embodiments, the laser source assembly 500 may sequentially provide beams of three primary colors (beams of other colors may also be added on a basis of the beams of the three primary colors). Due to a phenomenon of visual perception of human eyes, what the human eyes see is white beams formed by mixing the beams of three primary colors. Alternatively, the laser source assembly 500 may also simultaneously output the beams of three primary colors, so as to continuously emit the white beams. The laser source assembly 500 may include a light-emitting device that may emit a laser beam of at least one color, such as a red laser beam, a blue laser beam, or a green laser beam.

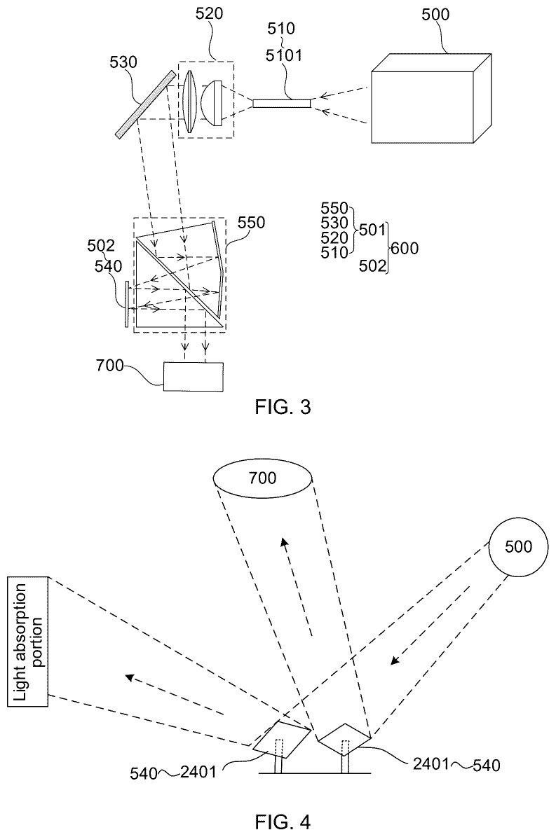

FIG. 2 is a diagram showing a beam path of a laser source assembly, a light modulation assembly, and a projection lens in a laser projection apparatus, in accordance with some embodiments. FIG. 3 is a diagram showing a principle of projection imaging by a laser projection apparatus, in accordance with some embodiments.

The illumination beams emitted by the laser source assembly 500 enter the light modulation assembly 600. As shown in FIGS. 2 and 3, the light modulation assembly 600 includes an illumination lens group 501 and a light modulation device (or the light valve) 502. The illumination lens group 501 is configured to receive the illumination beams provided by the laser source assembly 500 and transmit the illumination beams to the light modulation device 502 at a set angle and direction. The light modulation device 502 is configured to modulate the illumination beams to obtain the projection beams and reflect the projection beams into the projection lens 700.

In some embodiments, as shown in FIGS. 2 and 3, the illumination lens group 501 includes a light-homogenizing component 510, a lens group 520, and a prism group 550. The light-homogenizing component 510 is configured to receive the illumination beams provided by the laser source assembly 500 and homogenize the illumination beams. The lens group 520 is configured to converge the illumination beams exiting from the light-homogenizing component 510 to the prism group 550. The prism group 550 is configured to reflect the illumination beams to the light modulation device 502.

In some embodiments, as shown in FIGS. 2 and 3, the light-homogenizing component 510 includes a light pipe 5101. A light outlet of the light pipe 5101 may be in a shape of a rectangle, so as to have a shaping effect on a beam spot. In this way, the shape of the beam spot of the illumination beams exiting from the light pipe 5101 may match a rectangular laser-receiving surface of the light modulation device 502. Alternatively, the light-homogenizing component 510 may include a fly-eye lens. The fly-eye lens may homogenize the incident illumination beams and shape the illumination beams, so as to output a rectangular beam spot.

In some embodiments, as shown in FIGS. 2 and 3, the illumination lens group 501 further includes a reflector 530. The reflector 530 is located on a laser-exit side of the lens group 520 and configured to reflect the illumination beams exiting from the lens group 520 to the prism group 550.

In some embodiments, as shown in FIG. 3, the light modulation device 502 includes a digital micromirror device (DMD) 540.

The DMD 540 is a core component in the light modulation assembly 600 and configured to modulate the illumination beams provided by the laser source assembly 500 with image signals. That is to say, the digital micromirror device 540 controls the illumination beams to display different luminance and gray scales according to different pixels in an image to be projected, so as to finally produce an optical image.

FIG. 4 is a schematic diagram showing operation of micromirrors, in accordance with some embodiments. As shown in FIG. 4, the digital micromirror device 540 includes thousands of micromirrors 2401 that may be individually driven to rotate. A laser beam reflected by the micromirror 2401 at a negative deflection angle is referred to as an OFF laser beam, and the OFF laser beam is an ineffective laser beam.

With the miniaturization trend of light-emitting devices, a size of product is continuously reduced through iterations, resulting in an increase in the sealing difficulty of the light-emitting devices. Current soldering methods are difficult to achieve high airtightness and have problems such as solder overflow and glass stress. Glass stress may refer to the local thermal stress caused by a large temperature difference between the inner and outer parts of the glass in the soldering region due to the poor thermal conductivity of glass, which occurs when a high-energy laser beam rapidly heats the soldering region, resulting in local thermal expansion of the soldering portion during soldering.

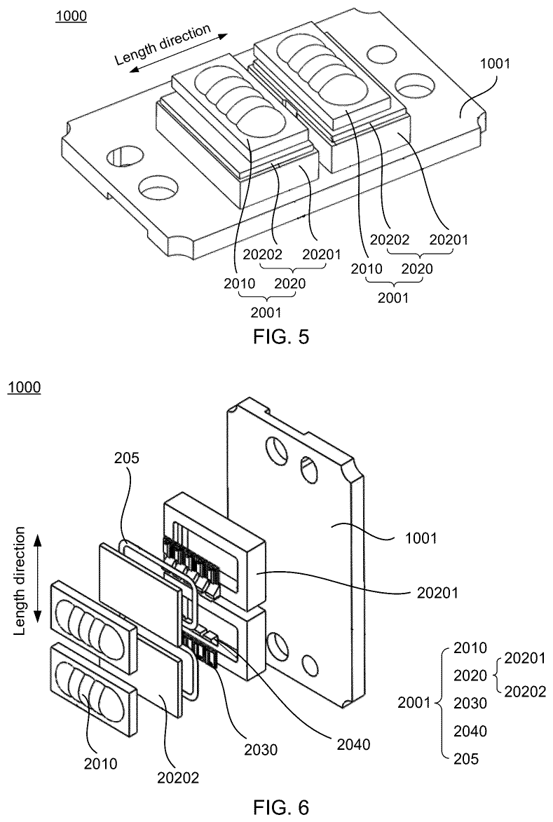

FIG. 5 is a diagram showing a structure of a light-emitting device in the related art. FIG. 6 is an exploded view of a light-emitting device in the related art.

Generally, as shown in FIGS. 5 and 6, a light-emitting device 1000 includes a substrate 1001 and at least one light-emitting assembly 2001. The light-emitting assembly 2001 includes a collimating portion 2010 (e.g., a collimating lens), a package 2020, a laser chip 2030, and a light deflecting component 2040 (e.g., a reflecting prism). The laser chip 2030 and the light deflecting component 2040 are disposed in the package 2020. The package 2020 includes an accommodating structure 20201 and a cover plate 20202. The cover plate 20202 is connected to the accommodating structure 20201 to form a sealed space. The sealed space is configured to accommodate the laser chip 2030 and the light deflecting component 2040.

As shown in FIGS. 5 and 6, at least one the light-emitting assembly 2001 includes a plurality of light-emitting assemblies 2001. The plurality of light-emitting assemblies 2001 are spaced apart from each other along a length direction of the substrate 1001. The laser chip 2030 and the light deflecting component 2040 are fixed in the package 2020 by a low-temperature sintering process with nano-metal paste. The thermal conductivity and mechanical reliability at high temperatures of the sintered laser chip 2030 are significantly improved. The light deflecting component 2040 is configured to deflect a laser beam emitted by the laser chip 2030 by 90°, so that the laser beam exits in a direction perpendicular to the substrate 1001. The reflected laser beam passes through the cover plate 20202 and finally exits after being collimated by the collimating portion 2010.

The laser chip 2030 is an active device and needs to be packaged in a dust-free, dry, and high air tightness space, to prevent water vapor and oxygen from entering this space, thereby ensuring the long-term operational reliability of the light-emitting device 1000.

Gold-tin alloy solder is a commonly used brazing filler material for hermetic packaging of the package 2020. Gold-tin alloy has high strength and excellent wettability. The wettability may refer to a property of the gold-tin alloy to form a uniform and dense wetting layer on a surface of a material when the gold-tin alloy is in contact with the surface of the material. The wetting layer may rapidly spread and uniformly cover the surface of the material, filling micro-pores and depressions, so as to form a stable contact interface.

As shown in FIG. 6, the light-emitting assembly 2001 further includes a soldering lug 205. The soldering lug 205 may be manufactured in advance from the gold-tin alloy solder. A thickness of the soldering lug 205 may be adjusted according to requirements, and the thickness of the soldering lug 205 is substantially uniform.

Generally, in the process of achieving alloy eutectic sealing by means of preformed soldering lug 205, it is required to plate gold on a soldering surface (e.g., at least a portion of a contact surface between the cover plate 20202 and the accommodating structure 20201). In this way, when the temperature rises to a melting point of the solder, the solder melts and fills a gap between the cover plate 20202 and the accommodating structure 20201, thereby achieving airtightness. The soldering lug 205 is usually prefabricated at the cover plate 20202. In the soldering process, the soldering lug 205 is heated after the soldering lug 205 is in contact with the accommodating structure 20201, thereby completing the soldering. When the soldering lug 205 melts and is subjected to some pressure, the solder in a molten state is very easily to overflow a sealing region (e.g., a contact region between the cover plate 20202 and the accommodating structure 20201), resulting in insufficient solder and easy formation of soldering voids. The soldering voids refer to holes or gaps formed when a soldering seam is not completely filled in the soldering process. Moreover, the overflowed solder may easily flow into the sealed space, thereby affecting the laser chip 2030.

To this end, a light-emitting device 2000 is provided in some embodiments of the present disclosure. The light-emitting device 2000 includes a plurality of first sealing portions. Two adjacent first sealing portions are in contact with each other by changing their own physical forms, so as to seal the accommodating structure and cover plate, thereby enhancing the airtightness of the soldering, preventing the solder from overflowing, and avoiding affecting the laser chips.

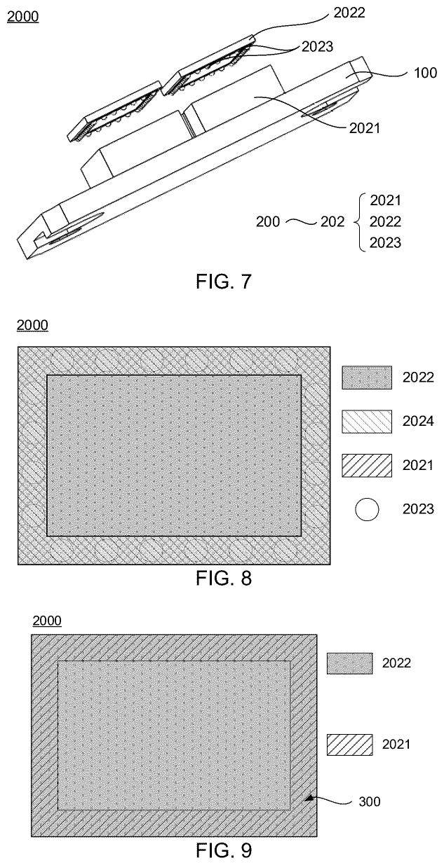

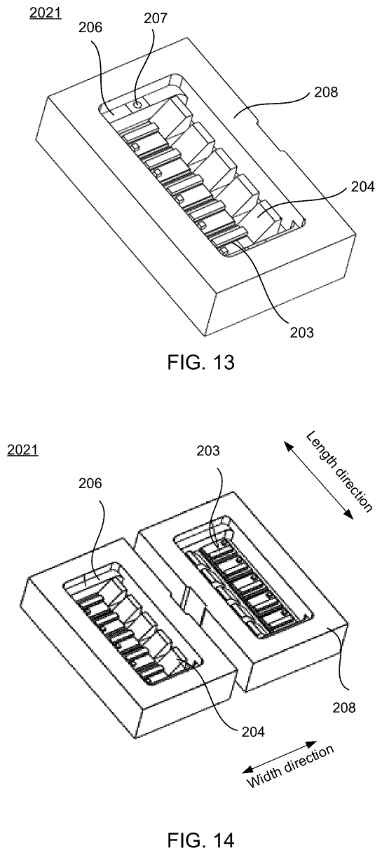

FIG. 7 is a diagram showing a structure of a light-emitting device, in accordance with some embodiments. As shown in FIG. 7, the light-emitting device 2000 includes a substrate 100 and a light-emitting assembly 200. The substrate 100 includes an electrical connection structure. The light-emitting assembly 200 is fixed on a side of the substrate 100. The substrate 100 is configured to support and fix the light-emitting assembly 200 and electrically connected to the light-emitting assembly 200, so as to provide a specific electrical signal to the light-emitting assembly 200, thereby enabling the light-emitting assembly 200 to emit laser beams. The light-emitting assembly 200 includes a package 202, a laser chip 203 (as shown in FIGS. 13 and 14), a light deflecting component 204 (as shown in FIGS. 13 and 14), and a conductive structure. The laser chip and light deflecting component are disposed in the package 202, and the conductive structure is disposed on a side of the package 202 facing the substrate 100 and is connected to the electrical connection structure. In this way, the light-emitting assembly 200 may be electrically connected to the substrate 100 through the conductive structure and the electrical connection structure.

As shown in FIG. 7, the package 202 includes an accommodating structure 2021, a cover plate 2022, and a plurality of first sealing portions 2023. The accommodating structure 2021 is disposed on the substrate 100, and a side of the accommodating structure 2021 away from the substrate 100 is recessed to form a cavity. The cover plate 2022 is covered on the accommodating structure 2021 to close the cavity, so as to form a sealed space. The plurality of first sealing portions 2023 are disposed between the accommodating structure 2021 and the cover plate 2022. The plurality of first sealing portions 2023 are configured to connect the accommodating structure 2021 and the cover plate 2022, to seal a gap at the joint between the accommodating structure 2021 and the cover plate 2022.

It will be noted that the plurality of first sealing portions 2023 are separated from each other and arranged at intervals on a side of the cover plate 2022 facing the accommodating structure 2021 before the cover plate 2022 is soldered to the accommodating structure 2021. When the cover plate 2022 is soldered to the accommodating structure 2021, two adjacent first sealing portions 2023 are in contact with each other by changing their own physical forms, to seal the gap at the joint between the accommodating structure 2021 and the cover plate 2022. The physical form may include a solid state and a liquid state.

For example, when the cover plate 2022 is soldered to the accommodating structure 2021, two adjacent first sealing portions 2023 melt due to heating and change from the solid state to the liquid state, so that the two adjacent first sealing portions 2023 are in contact with each other to seal the gap at the joint between the accommodating structure 2021 and the cover plate 2022.

In some embodiments of the present disclosure, the accommodating structure 2021 and the cover plate 2022 are sealed by means of the plurality of first sealing portions 2023, so that the laser chips disposed in the package 202 are isolated from the outside, which ensures the long-term reliable operation of the light-emitting device 2000. The plurality of first sealing portions 2023 are separated from each other, and each first sealing portion 2023 is an independent structure. Two adjacent first sealing portions 2023 are in contact with each other by changing their own physical forms after the plurality of first sealing portions 2023 change from the solid state to the liquid state, thereby achieving the purpose of sealing the gap at the joint between the accommodating structure 2021 and the cover plate 2022.

Compared with the method of sealing the accommodating structure 2021 and the cover plate 2022 by prefabricated soldering lug 205 in the related art, in some embodiments of the present disclosure, the accommodating structure 2021 and the cover plate 2022 are sealed by the plurality of first sealing portions 2023, which may prevent soldering voids caused by the overflow of the first sealing portions 2023 and improve airtightness. In addition, it is also possible to prevent the overflow of the first sealing portions 2023 from affecting the laser chips.

FIG. 8 is a diagram showing another structure of a light-emitting device, in accordance with some embodiments. In some embodiments, as shown in FIG. 8, the light-emitting device 2000 further includes a second sealing portion 2024. Orthogonal projections of the plurality of first sealing portions 2023 on a plane where the cover plate 2022 is located at least partially overlap with an orthogonal projection of the second sealing portion 2024 on the plane where the cover plate 2022 is located. The second sealing portion 2024 satisfies at least one of the following: the second sealing portion 2024 is disposed on a side of the cover plate 2022 facing the accommodating structure 2021 and is located between the cover plate 2022 and the plurality of first sealing portions 2023; and, the second sealing portion 2024 is disposed on a side of the accommodating structure 2021 facing the cover plate 2022 and is located between the accommodating structure 2021 and the plurality of first sealing portions 2023. FIG. 8 shows an example where the second sealing portion 2024 is disposed on the side of the cover plate 2022 facing the accommodating structure 2021.

In some embodiments, the second sealing portion 2024 may be a coating structure, such as a metallization layer. For example, the metallization layer includes at least one material of titanium (Ti), platinum (Pt) and gold (Au), or at least one material of nickel (Ni) and Au, or at least one material of chromium (Cr) or Au. The plurality of first sealing portions 2023 may be disposed on the second sealing portion 2024. The plurality of first sealing portions 2023 cooperate with the second sealing portion 2024, to achieve the purpose of stably fixing the cover plate 2022 and the accommodating structure 2021, and sealing the gap at the joint between the accommodating structure 2021 and the cover plate 2022.

FIG. 9 is a diagram showing yet another structure of a light-emitting device, in accordance with some embodiments. In some embodiments, as shown in FIG. 9, the light-emitting device 2000 further includes two sealing regions 300. The two sealing regions 300 are a first sealing region and a second sealing region, respectively. The first sealing region is located on the side of the accommodating structure 2021 proximate to the cover plate 2022; the second sealing region corresponds to the first sealing region and is located on the side of the cover plate 2022 proximate to the accommodating structure 2021. The plurality of first sealing portions 2023 are disposed within the first sealing region and the second sealing region. An orthogonal projection of the second sealing region on the plane where the substrate 100 is located at least partially overlaps with an orthogonal projection of the first sealing region on the plane where the substrate 100 is located. The first sealing region and the second sealing region are metallization layers. The first sealing portions 2023 connect the first sealing region and the second sealing region, to seal the gap at the joint between the accommodating structure 2021 and the cover plate 2022.

In some embodiments, at least one of the first sealing region and the second sealing region may include the second sealing portion 2024. For example, in a case where the second sealing portion 2024 is disposed on the side of the cover plate 2022 proximate to the accommodating structure 2021, the second sealing region includes the second sealing portion 2024; in a case where the second sealing portion 2024 is disposed on the side of the accommodating structure 2021 proximate to the cover plate 2022, the first sealing region includes the second sealing portion 2024. It may be understood that the second sealing portion 2024 may also be disposed independently of the first sealing region or the second sealing region. For example, the second sealing portion 2024 may be connected to the first sealing region or the second sealing region.

In addition, it may be understood that the second sealing portion 2024 satisfies at least one of the following: an orthogonal projection of the second sealing portion 2024 on a surface of the cover plate 2022 proximate to the accommodating structure 2021 is within the second sealing region; and an orthogonal projection of the second sealing portion 2024 on a surface of the accommodating structure 2021 proximate to the cover plate 2022 is located within the first sealing region.

In some embodiments, the sealing regions 300 may be insulated from a circuit structure (e.g., the conductive structure and the electrical connection structure) in the light-emitting device 2000.

The reliability of the connections between the first sealing portions 2023 and the cover plate 2022 and between the first sealing portions 2023 and the accommodating structure 2021 may be improved by providing the sealing regions 300. In some embodiments, the sealing region 300 may be configured with a solution similar to that in FIG. 8 in combination with the material, surface flatness, and insulation performance of the sealing regions 300. In this way, it is possible to improve the sealing reliability between the accommodating structure 2021 and the cover plate 2022.

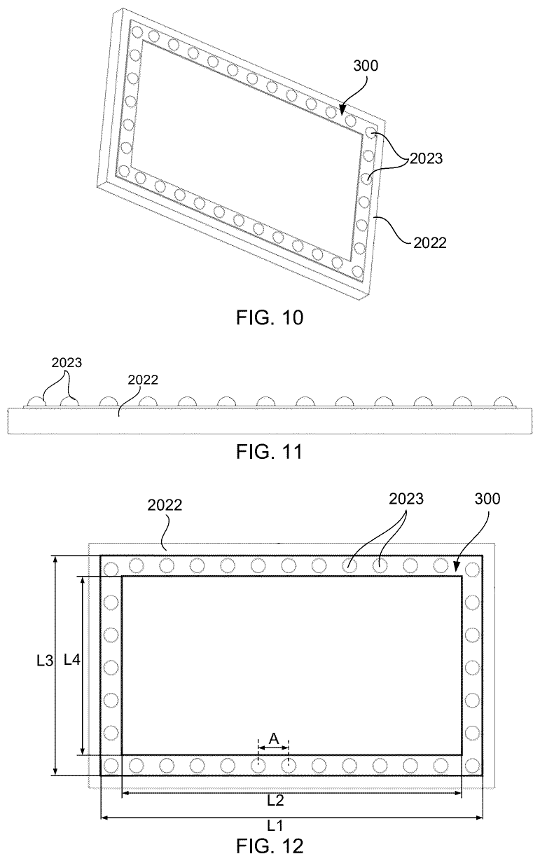

FIG. 10 is a diagram showing a structure of a cover plate and a plurality of first sealing portions, in accordance with some embodiments. FIG. 11 is a diagram showing another structure of a cover plate and a plurality of first sealing portions, in accordance with some embodiments. In some embodiments, as shown in FIGS. 10 and 11, the plurality of first sealing portions 2023 are disposed within the second sealing region. The first sealing portions 2023 each have a hemispherical shape, and there is an interval between two adjacent first sealing portions 2023.

As shown in FIGS. 10 and 11, the first sealing portions 2023 are hemispherical metal solder balls, and the first sealing portions 2023 may be made of the gold-tin alloy. There is an interval between two adjacent metal solder balls disposed on the cover plate 2022. The shape of the metal solder ball is easily changed under pressure, so that two adjacent metal solder balls may extend toward each other and be in contact with each other, thereby achieving the purpose of sealing the gap between the cover plate 2022 and the accommodating structure 2021. The metal solder balls may have a disc shape after being subjected to pressure.

Compared with the soldering method using the soldering lug 205 in the related art, the metal solder balls are in contact with each other by extension to seal the gap between the accommodating structure 2021 and the cover plate 2022, which may prevent the solder from overflowing, thereby preventing the soldering voids and the overflowed solder from affecting the laser chips 203.

FIG. 12 is a diagram showing yet another structure of a cover plate and a plurality of first sealing portions, in accordance with some embodiments. In some embodiments, as shown in FIG. 12, the sealing region 300 has an annular shape. An area of the sealing region 300 is defined as S, a distance between the accommodating structure 2021 and the cover plate 2022 is defined as H, the number of the plurality of hemispherical first sealing portions 2023 is M, and a radius of the hemispherical first sealing portion 2023 is R. In this case, the area S of the sealing region 300, the distance H between the accommodating structure 2021 and the cover plate 2022, the number M of the plurality of first sealing portions 2023, and the radius R of the first sealing portion 2023 satisfy Formula (1).

$$\frac{2}{3} π {R}^{3} \times M \geq S \times H \qquad Formula ( 1 )$$

It may be understood that Formula (1) means that a total volume of the plurality of first sealing portions 2023 is greater than or equal to a volume of a soldering region. The soldering region is a region defined by the sealing regions 300, the accommodating structure 2021, and the cover plate 2022.

As shown in FIG. 12, by performing eutectic soldering between the accommodating structure 2021 and the cover plate 2022 with the hemispherical first sealing portions 2023, unfilled regions of the first sealing portions 2023 may be reduced, and the first sealing portions 2023 in a high-temperature molten state may fill the sealing regions 300, thereby ensuring the airtight effect.

In some embodiments, the radius R of the first sealing portion 2023 and the distance between two adjacent first sealing portions 2023 are related a thickness of the first sealing portion 2023 after being expanded due to pressure and soldering. As shown in FIG. 12, outer side lengths of any sealing region 300 are defined to include a first length L1 and a first width L3, inner side lengths of any sealing region 300 are defined to include a second length L2 and a second width L4, a total volume of the plurality of first sealing portions 2023 is V. If the plurality of first sealing portions 2023 exactly fill the space corresponding to the sealing regions 300 between the accommodating structure 2021 and the cover plate 2022, the total volume V of the plurality of first sealing portions 2023 satisfies Formula (2) and Formula (3).

$$V = {V}_{1} \qquad Formula ( 2 )$$

$${V}_{1} = S \times H = ( L 1 \times L 3 - L 2 \times L 4 ) \times H \qquad Formula ( 3 )$$

In an ideal case, the total volume V of the plurality of first sealing portions 2023 in some embodiments of the present disclosure is equal to a target volume V₁. Considering the error in the accuracy of the total volume of the first sealing portions 2023, the total volume V of the plurality of first sealing portions 2023 may be set to be slightly greater than the target volume V₁. In some embodiments, the total volume V of the first sealing portions 2023 may exceed the target volume V₁ by up to 10%. A volume V₂ of any first sealing portion 2023 with a spherical shape satisfies Formula (4).

$${V}_{2} = \frac{4}{3} π {R}^{3} \qquad Formula ( 4 )$$

A volume V₃ of any hemispherical first sealing portion 2023 is half the volume V₂ of the first sealing portion 2023 with a spherical shape, as shown in Formula (5).

$${V}_{3} = \frac{2}{3} π {R}^{3} \qquad Formula ( 5 )$$

Therefore, in a case where the plurality of first sealing portions 2023 each are in a hemispherical shape, the total volume V of the plurality of first sealing portions 2023 satisfies Formula (6) and Formula (7).

$$V = M \times \frac{2}{3} π {R}^{3} \qquad Formula ( 6 )$$

$$( 1 + 10 \% ) \times S \times H \geq V \geq S \times H \qquad Formula ( 7 )$$

In some embodiments, a perimeter of any sealing region 300 is defined as L, and a distance between two adjacent hemispherical first sealing portions 2023 is defined as A. In this case, the perimeter L of the sealing region 300, the distance A between two adjacent hemispherical first sealing portions 2023, and the number M of the first sealing portions 2023 satisfy Formula (8).

$$A \times M = L \qquad Formula ( 8 )$$

As shown in FIG. 12, the perimeter L of the sealing region 300 is approximately a sum (i.e., L=L1+L2+L3+L4) of the first length L1, the second length L2, the first width L3, and the second width L4. The distance A between two adjacent hemispherical first sealing portions 2023 is defined as a distance between circle centers of surfaces of the two adjacent first sealing portions 2023 proximate to the cover plate 2022. To enable the plurality of first sealing portions 2023 to fill the sealing region 300, the perimeter L of the sealing region 300, the distance A between the circle centers of the surfaces of two adjacent first sealing portions 2023 proximate to the cover plate 2022, and the number M of the first sealing portions 2023 satisfy Formula (8).

It may be found, according to Formulas (6), (7) and (8), that in a case where the distance H between the accommodating structure 2021 and the cover plate 2022 and a size of the sealing regions 300 are determined, a relationship between the number M of the first sealing portions 2023 and the radius R of the first sealing portion 2023 may be obtained. The distance H between the accommodating structure 2021 and the cover plate 2022 may refer to a thickness of the first sealing portion 2023 after the accommodating structure 2021 and the cover plate 2022 are sealed, hereinafter referred to as a sealing thickness. The sealing thickness may also be a distance between the cover plate 2022 and the accommodating structure 2021 in a direction perpendicular to the plane where the substrate 100 is located.

In some embodiments, in the process of fabricating the first sealing portions 2023, the radius R of the first sealing portion 2023 is greater than or equal to 5 μm and less than or equal to 300 μm (i.e., 5 μm≤R≤300 μm), inclusive. For example, the radius R of the first sealing portion 2023 is 5 μm, 100 μm, 200 μm, 250 μm or 300 μm. Different values of the radius R of the first sealing portion 2023 correspond to different sealing thicknesses.

For a package 202 (e.g., a small-sized package) with a volume less than a first preset threshold, the sealing thickness may be greater than or equal to 20 μm, inclusive, correspondingly, the radius of the hemispherical first sealing portion 2023 may be greater than or equal to 40 μm, inclusive; alternatively, the sealing thickness may be less than or equal to 50 μm, inclusive, correspondingly, the radius of the hemispherical first sealing portion 2023 may be less than or equal to 100 μm, inclusive; alternatively, the sealing thickness may be greater than or equal to 20 μm and less than or equal to 50 μm, inclusive, correspondingly, the radius of the hemispherical first sealing portion 2023 may be greater than or equal to 40 μm and less than or equal to 100 μm, inclusive. For example, the sealing thickness is 20 μm, 25 μm, 30 μm, 40 μm or 50 μm, and the radius of the hemispherical first sealing portion 2023 is 40 μm, 50 μm, 70 μm, 90 μm or 100 μm.

For a package 202 with a volume greater than the first preset threshold, the sealing thickness may be greater than or equal to 50 μm, inclusive, correspondingly, the radius of the hemispherical first sealing portion 2023 may be greater than or equal to 120 μm, inclusive; alternatively, the sealing thickness may be less than or equal to 100 μm, inclusive, correspondingly, the radius of the hemispherical first sealing portion 2023 may be less than or equal to 180 μm, inclusive; alternatively, the sealing thickness may be greater than or equal to 50 μm and less than or equal to 100 μm, inclusive, correspondingly, the radius of the hemispherical first sealing portion 2023 may be greater than or equal to 120 μm and less than or equal to 180 μm, inclusive. For example, the sealing thickness is 50 μm, 60 μm, 70 μm, 90 μm or 100 μm, and the radius of the hemispherical first sealing portion 2023 is 120 μm, 140 μm, 150 μm, 170 μm or 180 μm. This may improve the sealing strength and increase the contact areas between the first sealing portions 2023 and the cover plate 2022 and between the first sealing portions 2023 and the accommodating structure 2021.

The required sealing thickness may be obtained by adjusting the pressure applied to the cover plate 2022 and the distance between two adjacent first sealing portions 2023. In a case where the radius of the hemispherical first sealing portion 2023 is within the radius range described above (e.g., being greater than or equal to 40 μm and less than or equal to 100 μm, inclusive; or being greater than or equal to 120 μm and less than or equal to 180 μm, inclusive), the ideal soldering effect may be achieved by controlling the pressure applied in the sealing process. In this way, in a case where the first sealing portions 2023 made of the gold-tin alloy material are used for sealing, the first sealing portions 2023 may also diffuse uniformly and densely as the temperature increases.

In a case where the radius of the hemispherical first sealing portion 2023 is greater than or equal to 5 μm and less than or equal to 40 μm, inclusive, for example, in a case where the radius of the hemispherical first sealing portion 2023 is 5 μm, 15 μm, 20 μm, 35 μm or 40 μm, the sealing contact area is small and the sealing thickness is thin, which may easily cause a phenomenon such as cold soldering or pseudo soldering of the solder joint in the sealing regions 300, reducing the reliability and environmental adaptability of the light-emitting device 2000. Therefore, the first sealing portions 2023 with the radius range described above are suitable for packages 202 (e.g., packages 202 for single-chip packaging) with a small size and a sealing region 300 having a small area.

In a case where the radius of the hemispherical first sealing portions 2023 is greater than or equal to 200 μm and less than or equal to 300 μm, inclusive, for example, in a case where the radius of the hemispherical first sealing portions 2023 is 200 μm, 220 μm, 250 μm, 280 μm or 300 μm, inclusive, the first sealing portions 2023 are prone to overflow in the sealing process. Therefore, it is necessary to strictly control parameters such as pressure and temperature, which increases the difficulty of the sealing process. In this case, it is difficult to control the sealing thickness due to the large radius of the first sealing portions 2023, which may easily cause uneven thickness of the first sealing portions 2023. Moreover, as the volume of the first sealing portions 2023 increases, the cost will also increase. Therefore, the first sealing portions 2023 with the radius range described above are suitable for packages 202 (e.g., large-sized packages 202) with a large size and a sealing region 300 having a large area.

In a case where the radius of the first sealing portion 2023 and the size of the package 202 are determined, the required sealing thickness may also be achieved by adjusting the number of the first sealing portions 2023. In a case where the size of the package 202 is determined, the smaller the radius of the first sealing portion 2023 is, the more first sealing portions 2023 are required. In some embodiments, in a case where the number of first sealing portions 2023 is within a range of 100 to 300, inclusive, the number of first sealing portions 2023 is small, so that first sealing portions 2023 (i.e., first sealing portions 2023 with a large radius) with a radius greater than a second preset threshold may be used for sealing. For small-sized packages 202, in a case where the radius of the first sealing portion 2023 is small, the number of the first sealing portions 2023 may be within a range of 4,000 to 8,000, inclusive.

In some examples, the number of the first sealing portions 2023 is within a range of 500 to 2,000, inclusive. A uniform sealing thickness may be obtained at this number by adjusting the radius of the first sealing portion 2023, thereby achieving a good sealing effect.

The description mentioned above is mainly given by considering an example in which the first sealing portions 2023 each are in a hemispherical shape. Of course, in some embodiments, the first sealing portions 2023 may also be in other shapes, such as a cube, cuboid, sphere, ellipsoid, or tetrahedron.

In an example where the first sealing portions 2023 each are in a hemispherical shape, the radius of the first sealing portion 2023 is R, and a volume V₂ of any first sealing portion 2023 satisfies Formula (9).

$${V}_{2} = \frac{4}{3} π {r}^{3} \qquad Formula ( 9 )$$

Therefore, in a case where the plurality of first sealing portions 2023 each have a spherical shape, the total volume V of the plurality of first sealing portions 2023 may be set to satisfy Formula (10) and Formula (11).

$$V = M \times \frac{4}{3} π {R}^{3} \qquad Formula ( 10 )$$

$$( 1 + 10 \% ) \times S \times H \geq \frac{4}{3} π {R}^{3} \times M \geq S \times H \qquad Formula ( 11 )$$

The process for determining a total volume of a plurality of first sealing portions 2023 with other shapes is similar to the process described above, and details will not be repeated herein.

FIG. 13 is a diagram showing a structure of an accommodating structure, in accordance with some embodiments. FIG. 14 is a diagram showing a structure of a plurality of accommodating structures, in accordance with some embodiments. As shown in FIGS. 13 and 14, the accommodating structure 2021 includes a side wall 208 and a base plate. The side wall 208 is disposed on the base plate. The side wall 208 may be made of a ceramic material or a metal alloy material. The base plate is a surface mount region for the laser chip 203 and the light deflecting component 204. Considering the accuracy of the surface mount technology and heat dissipation, high flatness is required for the base plate. Therefore, the base plate may be made of a material with good heat dissipation, such as oxygen-free copper or diamond. The side wall 208 may be connected to the base plate by sintering, so as to form the accommodating structure 2021.

As shown in FIGS. 13 and 14, the accommodating structure 2021 further includes at least two step portions 206. The at least two step portions 206 are disposed on two sides of the side wall 208 in a length direction of the accommodating structure 2021. Any step portion 206 is provided with a metal film electrically connected to the base plate, so that the step portion 206 may be electrically connected to the base plate, thereby achieving the electrical connection between the light-emitting assembly 200 and the substrate 100. The accommodating structure 2021 further includes positioning portions 207. The positioning portion 207 is disposed in a middle portion of the step portion 206 in a width direction of the accommodating structure 2021, and the positioning portion 207 may serve as an identification region. For example, a global coordinate system is constructed based on the positioning portions 207 on the two sides. A rectangular portion between at least two step portions 206 is a circuit isolation region, ensuring that the electrical connections between the base plate and the at least two step portions 206 are independent of each other. An identification region may be disposed on a side of the side wall 208, so as to facilitate identifying an orientation or direction of the side wall 208 when the side wall 208 is mounted to the substrate 100.

The laser chip 203 may be soldered on a heat sink by means of an eutectic process. The main materials of the heat sink may include aluminum nitride (ALN) and silicon carbide (SiC). A dimension of a waveguide layer of the laser chip 203 in a fast axis direction is small, which makes the beam quality of the laser beam output by the laser chip 203 close to the diffraction limit and results in a large divergence angle of the laser beam. For laser chips 203 with different waveguide layer dimensions in the fast axis direction, the divergence angles of the laser beams output by the laser chips 203 may be within a range of 40° to 60°, inclusive. In a slow axis direction, a divergence angle of the laser beam output by the laser chip 203 may be within a range of 6° to 15°, inclusive, and a dimension of an active region of the laser chip is within a range of 100 μm to 500 μm, inclusive, so that the laser beam has poor beam quality. Herein, the fast axis direction is perpendicular to the slow axis direction.

The light deflecting component 204 may deflect the laser beam emitted by the laser chip 203 by 90° and then output the laser beam. The light deflecting component 204 may be made of a material such as borosilicate glass, quartz, or silicon. An anti-reflection film may be applied to a surface of the light deflecting component 204, so as to improve reflectivity. Since the laser chip 203 has a large divergence angle in the fast axis direction, a small portion of the laser beam emitted by the laser chip 203 does not form effective light, but instead exits from sides of the light deflecting component 204 to form a stray laser beam.

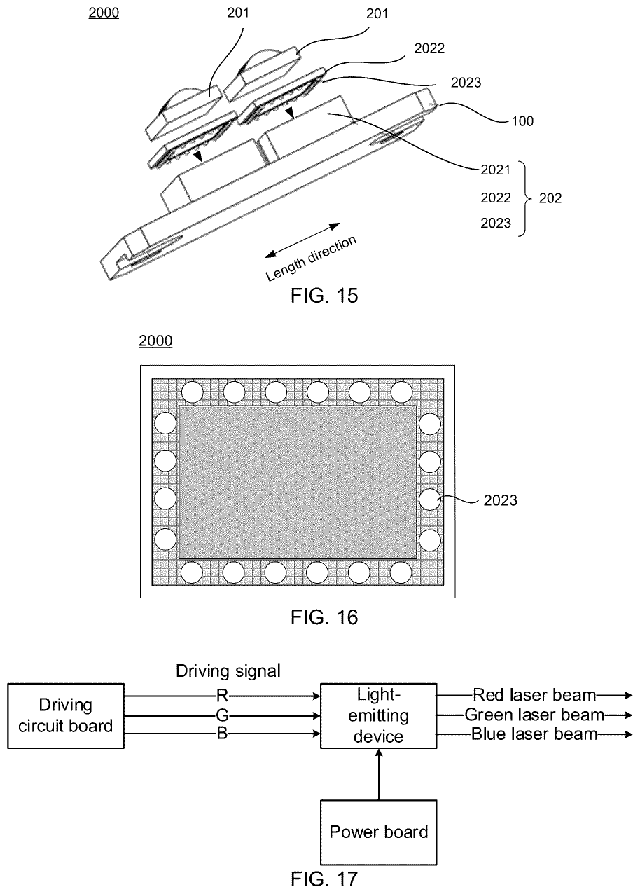

FIG. 15 is an exploded view of a light-emitting assembly, in accordance with some embodiments. In some embodiments, as shown in FIG. 15, the light-emitting assembly 200 further includes at least one collimating portion 201. The at least one collimating portion 201 is disposed on the cover plate 2022. The collimating portion 201 is configured to process the divergence angle of the laser beam emitted by the laser chip 203. For example, the collimating portion 201 collimates the laser beam emitted by the laser chip 203. Therefore, the collimating portion 201 needs to be designed based on the divergence angle of the laser chip 203 and an optical path of the light-emitting device 2000. A curvature of the collimating portion 201 may be adjusted for different performances of different light-emitting devices 2000. For example, a collimating portion 201 may have different curvatures. Alternatively, a collimating portion 201 may also have a single curvature to facilitate machining and reduce costs.

In some embodiments, a surface of the collimating portion 201 may be an aspheric surface or be a freeform surface. Alternatively, the collimating portion 201 may also use a Fresnel structure to achieve the function of compressing the divergence angle. The Fresnel structure is similar to a Fresnel lens. It will be noted that parameters of the surface of the collimating portion 201 are related to an optical path of the laser beam. Therefore, in the light-emitting device 2000, a position of the laser chip 203, a position of the light deflecting component 204, and the distance between the cover plate 2022 and the accommodating structure 2021 each are required to be set within a preset tolerance range. The number of collimating portions 201 may be the same as the number of light-emitting assemblies 200.

In some embodiments, as shown in FIG. 15, the at least one collimating portion 201 includes a plurality of collimating portions 201. The collimating portion 201 may be fixed by dispensing adhesive at the four corners of any collimating portion 201, and the adhesive dispensing positions are required to avoid an optically effective region. The optical effective region may refer to a region in which the collimating portion 201 may effectively process and transmit the laser beam. After the laser beam emitted by the laser chip 203 is reflected by the light deflecting component 204, the fast axis direction of the laser beam is parallel to a short side of the collimating portion 201, and the slow axis direction of the laser beam is parallel to a long side of the collimating portion 201. In this case, the plurality of collimating portions 201 may be arranged along the length direction of the substrate 100.

FIG. 16 is a diagram showing yet another structure of a light-emitting device, in accordance with some embodiments. The packaged light-emitting assembly 200 may be separated after the gap of the joint between the accommodating structure 2021 and the cover plate 2022 is sealed. After separating the cover plate 2022 from the accommodating structure 2021, as shown in FIG. 16, it may be seen, by observing the sealing region 300, that the intermetallic compound formed at the first sealing portion 2023 is distributed in a circular shape. Since a thickness of the intermetallic compound at the first sealing portion 2023 is thicker than that in other regions, a distinct color difference may be clearly observed between the region corresponding to the first sealing portion 2023 and the region where the solder is not filled.

The widespread application of miniaturized laser projection apparatus has increased the design difficulty of miniaturized light-emitting devices. In order to reduce the wiring required for interconnection between components in the light-emitting device and save space, a plurality of laser chips in the light-emitting device usually adopt a common anode or common cathode wiring mode. In the common anode wiring mode, anodes of a plurality of laser chips are connected to a positive electrode of the same power supply, while cathodes of a plurality of laser chips are connected to a plurality of driving circuits of the light-emitting device, respectively. In the common cathode wiring mode, cathodes of a plurality of laser chips are connected to a negative electrode of the same power supply, while anodes of the plurality of laser chips are connected to the plurality of driving circuits of the light-emitting device, respectively.

However, the common anode wiring mode makes it difficult to precisely control an input voltage of the laser chip, which not only causes power loss but also easily damages the laser chip; the common cathode wiring mode may effectively control the input voltage of the laser chip and reduce power consumption, but in a case where a plurality of laser chips are required to operate at the same time to increase brightness, the number of driving circuits increases, resulting in an increase in costs.

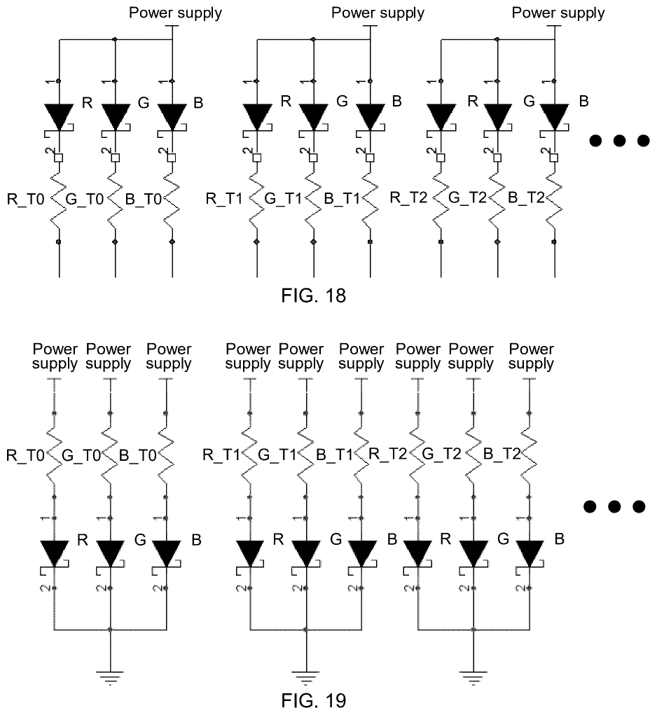

In the related art, as shown in FIG. 17, a driving circuit board is configured to transmit driving signals to the light-emitting device, and a power supply board is configured to supply power to the light-emitting device. In a case where the light-emitting device is powered on, the light-emitting device emits three colors of laser beams (e.g., a red laser beam, a blue laser beam, and a green laser beam) according to the received driving signals. FIG. 18 is a circuit diagram of a plurality of laser chips in a light-emitting device with a common anode wiring mode. FIG. 19 is a circuit diagram of a plurality of laser chips in a light-emitting device with a common cathode wiring mode. As shown in FIGS. 18 and 19, every three laser chips (e.g., a red laser chip R, a green laser chip G, and a blue laser chip B) form a light-emitting device, and the light-emitting device may emit the red laser beam, the green laser beam, and the blue laser beam. R_T, G_T, and B_T (e.g., R_T0, G_T0, B_T0; R_T1, G_T1, B_T1; R_T2, G_T2, B_T2) in the figures denote the driving circuits of the light-emitting device. In a case where a plurality of light-emitting devices are required to operate simultaneously to increase brightness, the number of driving circuits increases as the number of light-emitting devices increases, resulting in an increase in costs.

To end this, a light-emitting device is provided in some embodiments of the present disclosure. The light-emitting device includes a substrate and a light-emitting assembly. The light-emitting assembly is fixed on a connection pattern of the substrate, and laser chips emitting laser beams of the same color are connected in series and electrically connected to two corresponding first pads with different polarities through connection wires, a conductive structure, a conductive portion, and interconnection regions. In this way, power may be supplied to laser chips emitting laser beams of different colors separately, which solves the problem that the number of laser chips in use is limited by the number of driving circuits and cost. This allows the number of driving circuits to remain unchanged while the number of laser chips increases, effectively improving the operating efficiency of the driving circuits and reducing costs.

The light-emitting device in some embodiments of the present disclosure is described below with reference to the accompanying drawings.

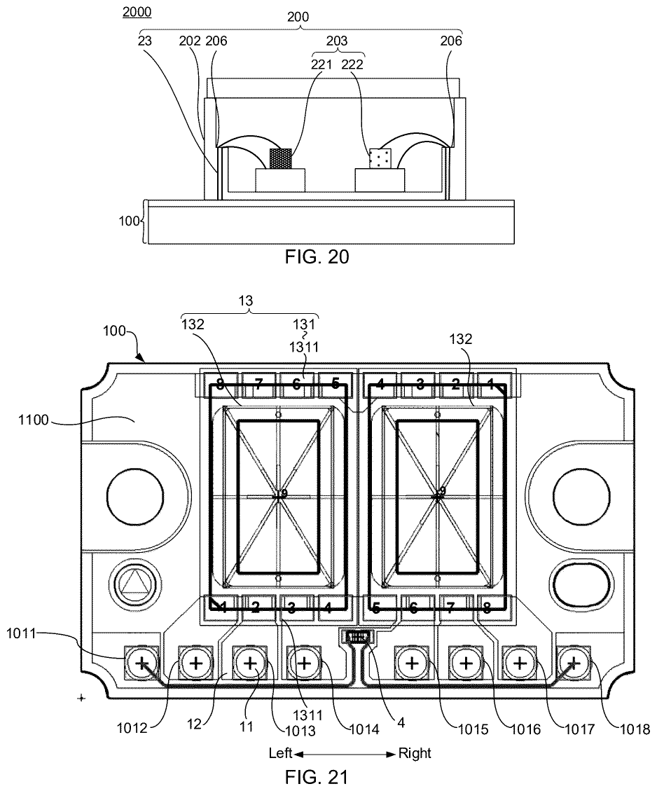

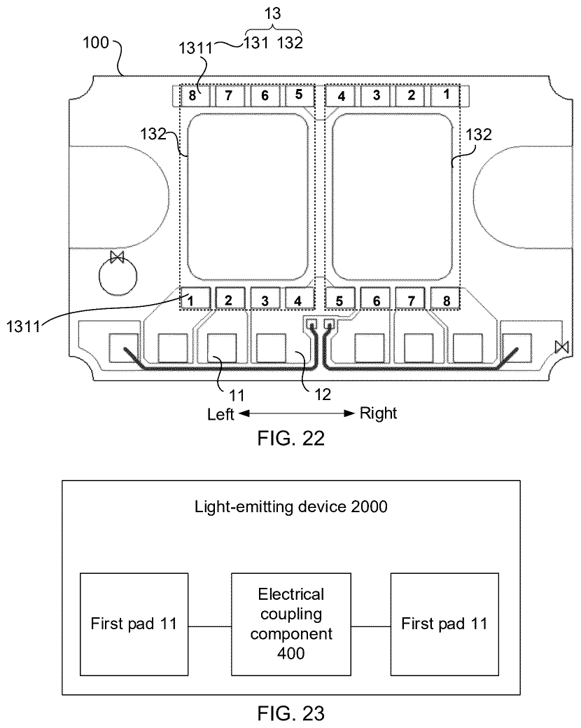

In some embodiments, as shown in FIG. 20, the light-emitting device 2000 includes a substrate 100 and a light-emitting assembly 200. The light-emitting assembly 200 is located on a side of the substrate 100. As shown in FIGS. 21 and 22, the substrate 100 includes a substrate body 1100, at least one connection pattern 13, a plurality of first pads 11, and a plurality of interconnection regions 12. The at least one connection pattern 13, the plurality of first pads 11 and the plurality of interconnection regions 12 are disposed on the substrate body.

In some embodiments, the plurality of interconnection regions 12 include a plurality of connection traces or a metal film layer. The plurality of connection traces or the metal film layer may be disposed inside the substrate body 1100. It may be understood that in some embodiments, the plurality of interconnection regions 12 may also be disposed on a side of the substrate body 1100 facing the light-emitting assembly 200.

In some embodiments, the plurality of first pads 11 are electrically connected to at least one connection pattern 13 through the plurality of interconnection regions 12. Moreover, the plurality of first pads 11 are also connected to a driving circuit and a power supply. For example, the plurality of first pads 11 may be connected to the power source through connectors, flexible substrates, epoxy glass substrates, or spring-type terminals.

In some embodiments, the plurality of first pads 11 include a plurality of groups of first pads 11. For example, any group of first pads 11 includes two first pads 11. Any group of first pads 11 includes a positive pad and a negative pad.

In some embodiments, the plurality of groups of first pads 11 satisfy at least one of the following: on a plane where the substrate 100 is located, the plurality of groups of first pads 11 are all located on the same side of at least one package and proximate to an edge of the substrate body; the first pads 11 of the same polarity of the plurality of groups of first pads 11 are arranged adjacently; and the first pads 11 of different polarities of any groups of first pads 11 are arranged adjacent to each other.

In some embodiments, any first pad 11 is a metal layer and in a rectangular shape.

In some embodiments, as shown in FIGS. 21 and 22, any one of the at least one connection pattern 13 includes a fixing portion 132. The fixing portion 132 is disposed on the substrate body and corresponds to a bottom wall of at least one package 202. For example, the fixing portion 132 is electrically connected to the bottom wall of any one of the at least one package 202. The light-emitting assembly 200 is disposed on (e.g., fixed to) the fixing portion 132, and the fixing portion 132 may be made of metal and in a rectangular shape. The connection pattern 13 further includes a conductive portion 131, and the conductive portion 131 is electrically connected to the light-emitting assembly 200. The region marked by a box with a thick solid black line in FIG. 21 is a position where the light-emitting assembly 200 is fixed on the substrate 100.

In some embodiments, at least one connection pattern 13 and the plurality of first pads 11 are disposed on the side of the substrate body 1100 facing the light-emitting assembly 200.

In some embodiments, as shown in FIG. 20, the light-emitting assembly 200 includes at least one package 202. Any one of the at least one package 202 includes a bottom wall, a side wall, and a sealing glass (e.g., the cover plate 2022). The bottom wall of the package 202 is parallel to the plane where the substrate 100 is located. The side wall of the package 202 is perpendicular to the plane where the substrate 100 is located. The sealing glass is located on a side of the side wall of the package 202 away from the bottom wall of the package 202. The bottom wall, side wall, and sealing glass of the package 202 form a sealed space. A lower surface of the bottom wall of the package 202 is connected to the fixing portion 132. At least one of the bottom wall and side wall of the package 202 may be provided with wires and be made of ceramic material.

In some embodiments, the side wall of the package 202 is made of ceramic, and the bottom wall of the package 202 is made of metal.

In some embodiments, as shown in FIG. 23, the light-emitting device 2000 further includes an electrical coupling component 400. The electrical coupling component 400 is disposed within a region of the substrate body proximate to the plurality of groups of first pads 11. The electrical coupling component 400 is electrically connected to the plurality of groups of first pads 11 and configured to connect to an external electrical signal source. For example, the electrical coupling component 400 may be a pin header.

In some embodiments, as shown in FIG. 20, the light-emitting assembly 200 further includes connection wires 23. The connection wires 23 are disposed inside at least one of the side wall and bottom wall of the package 202.

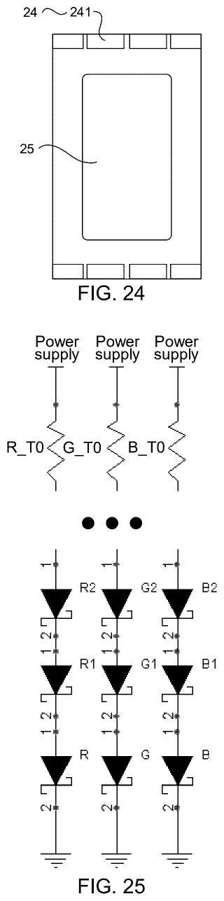

As shown in FIG. 24, the light-emitting assembly 200 further includes a conductive structure 24 and a first metal film 25 (i.e., a metal film). The conductive structure 24 and the first metal film 25 are disposed on a side (i.e., a lower surface of the bottom wall of the package 202) of the package 202 facing the substrate body. A position of the conductive structure 24 corresponds to a position of the conductive portion 131, and the conductive structure 24 is electrically connected to the conductive portion 131 and the connection wires 23. A position of the first metal film 25 corresponds to a position of the fixing portion 132, and the first metal film 25 is connected to the fixing portion 132.

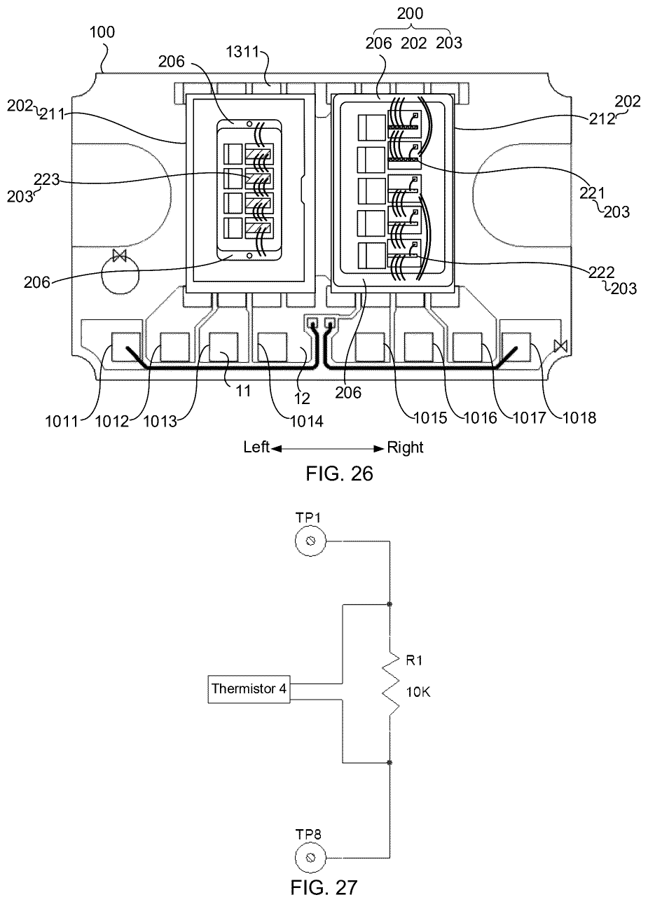

In some embodiments, as shown in FIGS. 20 and 26, the light-emitting assembly 200 further includes a plurality of step portions 206. The plurality of step portions 206 are disposed in any one of the packages 202 and are located on two sides of the package 202 in a length direction of the package 202. For example, as shown in FIG. 26, the plurality of step portions 206 include four step portions 206. Two of the four step portions 206 are located in a first package 211, and the other two of the four step portions 206 are located in a second package 212. An upper surface (i.e., a surface of the step portion 206 away from the substrate 100) of the step portion 206 is provided with a second metal film, and the second metal film is electrically connected to the conductive structure 24 through the connection wire 23. The first package 211 and the second package 212 will be described below.

In some embodiments, as shown in FIG. 20, the light-emitting assembly 200 further includes a plurality of laser chips 203, and the plurality of laser chips 203 are located in the package 202. For example, the plurality of laser chips 203 are located within the sealed space formed by the bottom wall, side wall, and sealing glass of the package 202. The plurality of laser chips 203 include at least two types of laser chips 203 that emit laser beams of different colors, and each type of laser chip 203 corresponds to a group of first pads 11.

The plurality of laser chips 203 may be electrically connected to the conductive structure 24 through the connection wires 23, and the conductive portion 131 may be electrically connected to the plurality of first pads 11 through the plurality of interconnection regions 12. In this way, the plurality of laser chips 203 may be electrically connected to the plurality of first pads 11.

In an example where the light-emitting assembly 200 includes the connection wires 23, laser chips 203 of the same type may be electrically connected to a corresponding group of first pads 11 through the connection wires 23, conductive structure 24, conductive portion 131 and interconnection regions 12, thereby achieving independent power supply for a plurality of types of laser chips 203.

For example, as shown in FIG. 20, the plurality of laser chips 203 include a first-type laser chip 221 and a second-type laser chip 222. The first-type laser chip 221 emits a blue laser beam, and the second-type laser chip 222 emits a red or green laser beam. Since the first-type laser chip 221 is electrically connected to a corresponding group of first pads 11, and the second-type laser chip 222 is electrically connected to another corresponding group of first pads 11, the substrate 100 includes at least four first pads 11.

It will be noted that FIG. 20 illustrates an example where the light-emitting device 2000 includes two types of laser chips 203, but this does not constitute a limitation on the light-emitting device 2000. In some other embodiments, the plurality of laser chips 203 may further include three types of laser chips 203, and the three types of laser chips 203 emit laser beams of different colors. The three types of laser chips 203 are electrically connected to three corresponding groups of first pads 11 through the connection wires 23, respectively, so that independent power supply for any one type of the three types of laser chips 203 is achieved, and the present disclosure does not limit the types of laser chips 203.

For example, as shown in FIG. 25, the light-emitting device 2000 includes three types of laser chips 203, namely red laser chips (e.g., R, R1 and R2), green laser chips (e.g., G, G1 and G2) and blue laser chips (e.g., B, B1 and B2). It will be noted that the red laser chips may emit red laser beams, the green laser chips may emit green laser beams, and the blue laser chips may emit blue laser beams. Since each type of laser chip 203 is connected in series with the corresponding power supply and driving circuit (e.g., R_T0, G_T0, and B_T0), the number of driving circuits may remain unchanged no matter how the number of laser chips 203 increases. In this way, it is possible to solve the problem that the number of laser chips 203 in use is limited by the driving circuit, and effectively improve the operating efficiency of the driving circuit and reduce costs.

In some embodiments, the substrate 100 may be made of copper and may be a single-sided printed circuit board (PCB). In this way, a back side of the substrate 100 (i.e., a side of the substrate 100 away from the light-emitting assembly 200) may have sufficient area for heat dissipation, which fabricates heat dissipation of the light-emitting device 2000. In addition, this substrate 100 may also enable the independent power supply for any type of laser chip 203 and meet the miniaturization design requirements of the light-emitting device 2000. The present disclosure does not limit the size of the substrate 100, and the size of the substrate 100 may be flexibly set according to the requirements. For example, the substrate 100 is a copper substrate with a width of 15.8 mm, a length of 26 mm, and a thickness of 1.6 mm.

In some embodiments, in a case where the substrate 100 is made of copper, the substrate 100 may have a thickness corresponding to 2 ounces (oz) of copper foil, about 70 μm.

In some embodiments, as shown in FIGS. 21 to 24, in the direction perpendicular to the plane where the substrate 100 is located, any one of the plurality of first pads 11 at least partially overlaps with any one of the plurality of interconnection regions 12, the connection pattern 13 at least partially overlaps with the plurality of interconnection regions 12, and the conductive structure 24 at least partially overlaps with the connection pattern 13.

In the direction perpendicular to the plane where the substrate 100 is located, there is an overlapping region between the first pad 11 and the interconnection region 12, and the overlapping region is a connection region between the first pad 11 and the interconnection region 12. It is conducive to improving the stability of the electrical connection and the electric current carrying capacity between the first pad 11 and the interconnection region 12 by increasing a connection area between the first pad 11 and the interconnection region 12. The first pad 11 at least partially overlaps with the interconnection region 12, which may be understood as follows: in the direction perpendicular to the plane where the substrate 100 is located, the first pad 11 is located within the interconnection region 12 (as shown in FIG. 21 or 22), or the first pad 11 partially overlaps with the interconnection region 12, and there is also a region where the first pad 11 does not overlap with (e.g., is staggered from) the interconnection region 12.

In the direction perpendicular to the plane where the substrate 100 is located, there is an overlapping region between the connection pattern 13 or the conductive portion 131 and the interconnection region 12, and the overlapping region is a connection region between the connection pattern 13 or the conductive portion 131 and the interconnection region 12. It is conducive to improving the stability of the electrical connection and the electric current carrying capacity between the connection pattern 13 or the conductive portion 131 and the interconnection region 12 by increasing a connection area between the connection pattern 13 or the conductive portion 131 and the interconnection region 12. In an example where there is an overlapping region between the conductive portion 131 and the interconnection region 12, the conductive portion 131 at least partially overlaps with the interconnection region 12, which may be understood as follows: in the direction perpendicular to the plane where the substrate 100 is located, the conductive portion 131 is located within the interconnection region 12 (as shown in FIG. 21 or 23), or the conductive portion 131 partially overlaps with the interconnection region 12, and there is also a region where the conductive portion 131 does not overlap with the interconnection region 12.

In this way, the first pad 11 may be electrically connected to the connection pattern 13 through the interconnection region 12.

In the direction perpendicular to the plane where the substrate 100 is located, the conductive structure 24 at least partially overlaps with the connection pattern 13. That is to say, there is an overlapping region between the conductive structure 24 and the connection pattern 13, thereby achieving the electrical connection between the conductive structure 24 and the connection pattern 13. The conductive structure 24 at least partially overlaps with the connection pattern 13, which may be understood as follows: in the direction perpendicular to the plane where the substrate 100 is located, the conductive structure 24 is located within the connection pattern 13, or the connection pattern 13 is located within the conductive structure 24, or the conductive structure 24 partially overlaps with the connection pattern 13, and there is also a region where the conductive structure 24 does not overlap with the connection pattern 13.

In some embodiments, as shown in FIGS. 21 and 22, the plurality of first pads 11 are proximate to the same side of the substrate 100 on the plane where the substrate 100 is located. In this way, the plurality of first pads 11 are also located on the same side of the package 202 after the package 202 is disposed on the substrate 100. This not only ensures the miniaturization of the light-emitting device 2000, but also improves the aesthetic appearance of the light-emitting device 2000 and facilitates manual soldering.

Of course, in some other embodiments, the plurality of first pads 11 may also be located on two opposite sides of the package 202 in the length or width direction of the package 202, so that independent power supply may also be achieved for any type of laser chip 203.

FIG. 20 illustrates an example where the plurality of laser chips 203 include the first-type laser chip 221 and the second-type laser chip 222, and the first-type laser chip 221 emits the blue laser beam and the second-type laser chip 222 emits the red or green laser beam. Of course, in some embodiments, the plurality of laser chips 203 may further include three types of laser chips 203.

For example, as shown in FIG. 26, the plurality of laser chips 203 include two first-type laser chips 221, three second-type laser chips 222, and four third-type laser chips 223, and the three types of laser chips emit laser beams of different colors. Laser chips 203 of the same type located in the same package 202 are connected in series and to a corresponding group of first pads 11. The number of first pads 11 electrically connected to the light-emitting assembly 200 is twice the number of types of laser chips 203.

A type of laser chip 203 emits a laser beam of one color. The first-type laser chip 221, second-type laser chip 222, and third-type laser chip 223 emit laser beams of different colors. For example, the first-type laser chip 221 emits a blue laser beam, the second-type laser chip 222 emits a green laser beam, and the third-type laser chip 223 emits a red laser beam; or the first-type laser chip 221 emits a green laser beam, the second-type laser chip 222 emits a blue laser beam, and the third-type laser chip 223 emits a red laser beam.

In some embodiments, as shown in FIG. 26, a wavelength of the laser beam emitted by the third-type laser chip 223 is greater than a wavelength of the laser beam emitted by the first-type laser chip 221 and a wavelength of the laser beam emitted by the second-type laser chip 222. For example, the third-type laser chip 223 emits a red laser beam with a wavelength of any value within a range of 622 nm to 760 nm, inclusive, the first-type laser chip 221 emits a blue laser beam with a wavelength of any value within a range of 435 nm to 450 nm, inclusive, and the second-type laser chip 222 emits a green laser beam with a wavelength of any value within a range of 492 nm to 577 nm, inclusive. In some other embodiments, the first-type laser chip 221, the second-type laser chip 222, and the third-type laser chip 223 may further emit laser beams of other colors, and the present disclosure is not limited thereto.

In some embodiments, as shown in FIG. 26, at least one type of the plurality of laser chips 203 is disposed in a package 202. All laser chips 203 emitting the laser beams of the same color in the same package 202 are connected in series and to a corresponding group of first pads 11.

For example, as shown in FIG. 26, at least one package 202 includes a first package 211 and a second package 212. The first package 211 and the second package 212 are arranged side by side in a length direction (e.g., the left-right direction in FIG. 26) of the light-emitting assembly 200.

In this case, four third-type laser chips 223 are disposed in the first package 211. The four third-type laser chips 223 are connected in series by wires (e.g., gold wires or bonding wires), and two ends of the series circuit are electrically connected to the second metal films on the step portions 206 on two sides of the third-type laser chips 223, respectively. The second metal films are electrically connected to the conductive structure 24 through the connection wires 23. The conductive structure 24 is electrically connected to the conductive portion 131. The conductive portion 131 is electrically connected to the corresponding two first pads 11 through the interconnection regions 12. In this way, the electrical connection between the four third-type laser chips 223 and the corresponding group of first pads 11 is achieved.

Two first-type laser chips 221 and three second-type laser chips 222 are disposed in the second package 212. Two first-type laser chips 221 are connected in series by wires, and two ends of the series circuit are electrically connected to two second metal films on a step portion 206, respectively. The two second metal films are electrically connected to the conductive structure 24 through the connection wires 23, and the conductive structure 24 is electrically connected to the conductive portion 131. The conductive portion 131 is electrically connected to the corresponding two first pads 11 through the interconnection regions 12. In this way, the electrical connection between the two first-type laser chips 221 and the corresponding group of first pads 11 is achieved.

The three second-type laser chips 222 are connected in series by wires, and two ends of the series circuit are electrically connected to two second metal films on another step portion 206, respectively. The two second metal films are electrically connected to the conductive structure 24 through the connection wires 23, and the conductive structure 24 is electrically connected to the conductive portion 131. The conductive portion 131 is electrically connected to the corresponding two first pads 11 through the interconnection regions 12. In this way, the electrical connection between the three first-type laser chips 221 and the corresponding group of first pads 11 is achieved.

It will be noted that FIG. 26 illustrates an example where the plurality of packages 202 include two packages 202, but the present disclosure is not limited to this. In some other embodiments, at least one package 202 may further include a package 202, and the first-type laser chip 221, the second-type laser chip 222 and the third laser chip 223 are located in the same package 202. Alternatively, at least one package 202 includes three packages 202, the first-type laser chip 221, the second-type laser chip 222 and the third-type laser chip 223 correspond to the three packages 202, respectively, and laser chips 203 of the same type are located in the same package 202. The present disclosure does not limit the number of packages 202.

In some embodiments, as shown in FIG. 21, the plurality of first pads 11 include four groups of first pads 11. The four groups of first pads 11 include: a first positive pad (R+) and a first negative pad (R−), a second positive pad (B+) and a second negative pad (B−), a third positive pad (G+) and a third negative pad (G−), and a fourth positive pad (NTC+) and a fourth negative pad (NTC−).

It will be noted that, as shown in FIG. 21, the first positive pad (R+) corresponds to a first positive pad 1012, the first negative pad (R−) corresponds to a first negative pad 1013, the second positive pad (B+) corresponds to a second positive pad 1015, the second negative pad (B−) corresponds to a second negative pad 1014, the third positive pad (G+) corresponds to a third positive pad 1016, the third negative pad (G−) corresponds to a third negative pad 1017, the fourth positive pad (NTC+) corresponds to a fourth positive pad 1011, and the fourth negative pad (NTC−) corresponds to a fourth negative pad 1018.

In some embodiments, as shown in FIG. 21, in the length direction (e.g., from left to right) of the substrate 100, the eight first pads 11 are arranged in the following order: the fourth positive pad (NTC+), the first positive pad (R+), the first negative pad (R−), the second negative pad (B−), the second positive pad (B+), the third positive pad (G+), the third negative pad (G−) and the fourth negative pad (NTC−). In this case, the fourth positive pad (NTC+) is adjacent to the first positive pad (R+), the first negative pad (R−) is adjacent to the second negative pad (B−), the second positive pad (B+) is adjacent to the third positive pad (G+), and the third negative pad (G−) is adjacent to the fourth negative pad (NTC−). In this way, by arranging the positions of the plurality of first pads 11 according to the principle of adjacent pads with the same polarity, it is possible to prevent the short circuit between the positive electrode and the negative electrode caused by soldering errors.

It may be understood that in some embodiments, two first pads 11 of any one group of the four groups of first pads 11 may also be interchanged in position. For example, the second negative pad and the second positive pad in FIG. 21 may also be interchanged in position, and the third positive pad and the third negative pad may also be interchanged in position. In this case, along the length direction (e.g., from left to right) of the substrate 100, the eight first pads 11 are arranged in the following order: the fourth positive pad, the first positive pad, the first negative pad, the second positive pad, the second negative pad, the third negative pad, the third positive pad and the fourth negative pad.

The present disclosure does not limit the type of the first pad 11. For example, as shown in FIG. 21, the first pad 11 may be configured as a cross-shaped pad. Of course, the first pad 11 may also be configured as other types of pads known to those skilled in the art.

In some embodiments, as shown in FIG. 21, the substrate 100 further includes a temperature-measuring component 4 (e.g., a thermistor). The temperature-measuring component 4 is connected to a corresponding group of first pads 11 through connection traces. The temperature-measuring component 4 is configured to detect heating conditions of laser chips 203. For example, the temperature-measuring component 4 may include a negative temperature coefficient (NTC) temperature-measuring component, or other types of temperature-measuring components known to those skilled in the art, and the present disclosure is not limited thereto.

In some embodiments, the temperature-measuring component 4 satisfies at least one of the following: the temperature-measuring component 4 is located in a middle region of an arrangement direction of the plurality of first pads 11; and the plurality of groups of first pads 11 are symmetrically arranged on two sides of the temperature-measuring component 4. As shown in FIGS. 21 and 27, the temperature-measuring component 4 is located on a side of the connection pattern 13 proximate to the eight first pads 11. The eight first pads 11 are symmetrically arranged on two sides of the temperature-measuring component 4. The group of first pads 11 (i.e., the fourth positive pad NTC+ and the fourth negative pad NTC−) corresponding to the temperature-measuring component 4 is located on an outermost side of the plurality of first pads 11 (that is, the two first pads 11 connected to the temperature-measuring component 4 are located on two sides of the other first pads 11, respectively), and the temperature-measuring component 4 is electrically connected to the fourth positive pad (NTC+) and the fourth negative pad (NTC−) through the corresponding interconnection regions 12. A circuit diagram of the temperature-measuring component 4 is shown in FIG. 27. In FIG. 27, TP1 denotes the fourth positive pad (NTC+) and TP8 denotes the fourth negative pad (NTC−).

In some embodiments, as shown in FIG. 24, the conductive structure 24 includes a plurality of second pads 241, and the second pads 241 are connected to the connection wires 23. The plurality of second pads 241 are disposed correspond to the side wall of at least one package 202. For example, the plurality of second pads 241 are connected to the side wall of at least one package 202. Correspondingly, as shown in FIGS. 21 and 22, the conductive portion 131 includes a plurality of third pads 1311, and any one of the plurality of third pads 1311 at least partially overlaps with the interconnection region 12 in the direction perpendicular to the plane where the substrate 100 is located.

In this case, the plurality of third pads 1311 are electrically connected to the plurality of second pads 241, respectively. The plurality of third pads 1311 are also electrically connected to the plurality of first pads 11 through the interconnection regions 12. The second pad 241 is welded with the connection wire 23, and the second pad 241 is connected to corresponding laser chip 203 through the connection wire 23. A plurality of laser chips 203 emitting laser beams of the same color in the same package 202 are connected in series. In this way, the laser chips 203 of the same type may be powered individually, which may avoid an increase in the number of driving circuits due to the increase in the number of laser chips 203, thereby helping to reduce costs.

In some embodiments, at least one package 202 includes the first package 211 and the second package 212, the plurality of laser chips 203 include the first-type laser chip 221, the second-type laser chip 222, and the third laser chip 223, the third-type laser chip 223 is disposed in the first package 211, and the first-type laser chip 221 and the second-type laser chip 222 are disposed in the second package 212. In this case, the conductive structure 24 may include eight second pads 241, any one of the packages 202 is provided with four second pads 241 arranged side by side, and the four second pads 241 are disposed proximate to the first pads 11.

Two second pads 241 on the second package 212 are connected to a first group of first pads 11, and two other second pads 241 on the second package 212 are connected to a second group of first pads 11. Two second pads 241 on the first package 211 that are away from the second package 212 are connected to a third group of first pads 11. One of the other two adjacent second pads 241 on the first package 211 that is proximate to the second package 212 is electrically connected to the second pad 241 on the second package 212 that is proximate to the first package 211.

In this case, the first metal films 25 are also disposed on the sides of the first package 211 and the second package 212 facing the substrate 100, respectively. The first metal film 25 corresponds to and is connected to the fixing portion 132, and the plurality of second pads 241 correspond to and are electrically connected to the plurality of third pads 1311, respectively. In this way, the light-emitting assembly 200 may be fixed and electrically connected to the substrate 100.

As shown in FIGS. 21, 22 and 26, the first package 211 and the second package 212 are fixed and electrically connected to the substrate 100 in the following manner: the fixing portion 132 of the connection pattern 13 on the right side is fixedly connected to the first metal film 25 on the side of the second package 212 facing the substrate 100; the four third pads 1311 corresponding to the four second pads 241 of the second package 212 are disposed proximate to the first pads 11; two of the four third pads 1311 are connected to a group of first pads 11 through interconnection regions 12, and the other two of the four third pads 1311 are connected to another group of first pads 11 through interconnection regions 12; the fixing portion 132 of the connection pattern 13 on the left side is fixedly connected to the first metal film 25 on the side of the first package 211 facing the substrate 100; the four third pads 1311 corresponding to the four second pads 241 of the first package 211 are disposed proximate to the first pads 11; two of the four third pads 1311 away from the connection pattern 13 on the right side are connected to a group of third pads 1311 through interconnection regions 12; at least one of the other two (e.g., the two third pads 1311 numbered 3 and 4 in FIG. 22) of the four third pads 1311 that is proximate to the right side is connected, through the same interconnection region 12, to the third pad 1311 (e.g., the third pad 1311 numbered 5 in FIG. 22), closest to the first package 211 on the left side, of the conductive portion 131 of the connection pattern 13 on the right side.

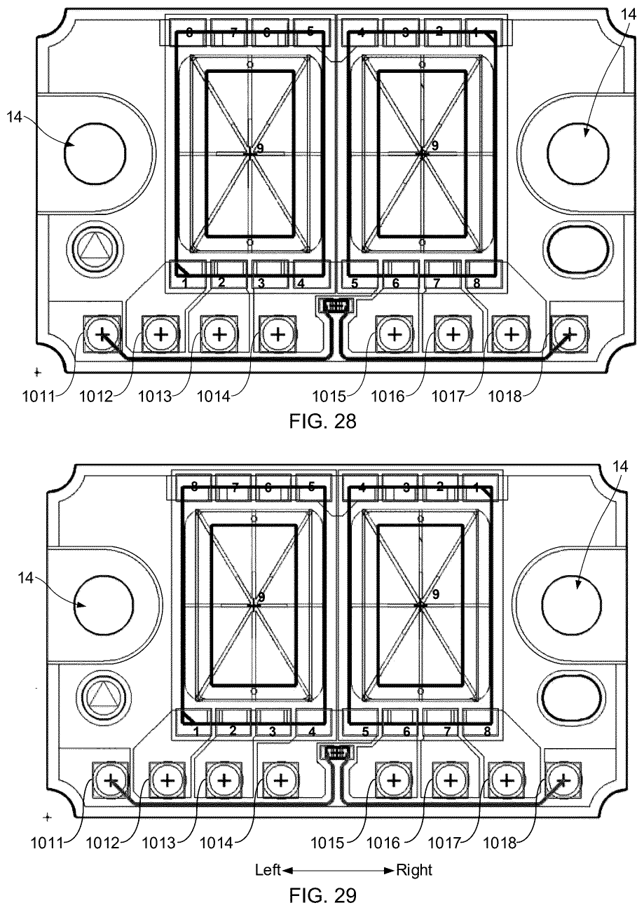

For example, as shown in FIG. 28, the third pads 1311 numbered 3 and 4 are electrically connected to the third pad 1311 numbered 5 through the interconnection region 12. For another example, as shown in FIG. 29, the third pad 1311 numbered 4 is electrically connected to the third pad 1311 numbered 5 through the interconnection region 12, and the third pad 1311 numbered 3 is electrically connected to the third pad 1311 numbered 2 through the interconnection region 12.

It will be noted that the connection pattern 13 on the right side corresponds to the second package 212, and the connection pattern 13 on the left side corresponds to the first package 211.

Positioning holes 14 (as shown in FIGS. 28 and 29) are required to be disposed on the substrate 100, if a distance between the package 202 and the positioning hole is less than or equal to 0.5 mm, inclusive, a region between the package 202 and the positioning hole is not suitable for wiring. Therefore, in some embodiments of the present disclosure, the second pads 241 are disposed within the region of the package 202 proximate to the first pads 11, and the second pads 241 are electrically connected to the corresponding first pads 11 through the third pads 1311 proximate to the first pads 11 and the interconnection regions 12.

In some other embodiments, in a case where the distance between the positioning hole and the package 202 and a distance between the two packages 202 satisfy the minimum wiring width, the second pads 241 may also be disposed within a region of the package 202 away from the first pads 11. In this case, the interconnection region 12 may also be disposed within the at least one of: a region on the substrate 100 between the positioning hole and the package 202, and a region on the substrate 100 between two packages 202. In this way, the third pads 1311 that are proximate to each other may be connected with each other through the interconnection region 12, and then the third pads 1311 may be electrically connected to the first pad 11, thereby increasing the wiring width and improving the electric current carrying capacity.

A plurality of electrical connection relationships between the light-emitting assembly 200 and the substrate 100 are described below by considering an example in which the substrate 100 includes eight first pads 11, the at least one package includes two packages, and the plurality of laser chips include three types of laser chips emitting laser beams of different colors.

As shown in FIG. 26, the eight first pads 11 are located on the same side of the two packages 202, and any one of the packages 202 is provided with four second pads 241 proximate to the first pads 11. The substrate corresponding to the first package 211 and the second package 212 is shown in FIG. 21 or 22. Correspondingly, the conductive portion 131 includes eight third pads 1311. To clearly describe the correspondence among the laser chips 203, the second pads 241, the third pads 1311, and the first pads 11, as shown in FIGS. 21 and 22, the eight third pads 1311 proximate to the first pads 11 are numbered. The four third pads 1311 corresponding to the four second pads 241 on the first package 211 are numbered 1 to 4, and the four third pads 1311 corresponding to the four second pads 241 on the second package 212 are numbered 5 to 8. It will be noted that there are two groups of numbers 1 to 8 in FIGS. 21 and 22, the two groups of numbers 1 to 8 are to indicate that the second package 212 may be obtained by rotating the first package 211 clockwise by 180°, and the eight third pads 1311 numbered 1 to 8 mentioned above refer to the group of numbers 1 to 8 that are proximate to the first pads 11 in FIGS. 21 and 22.

Moreover, the first-type laser chip 221 emits the blue laser beam, the second-type laser chip 222 emits the green laser beam, and the third-type laser chip 223 emits the red laser beam. A plurality of third-type laser chips 223 are packaged in the first package 211. The third-type laser chips 223 are electrically connected to two corresponding second pads 241 through connection wires 23 inside the first package 211, and the two second pads 241 are connected to two corresponding third pads 1311 (i.e., the third pads 1311 numbered 1 and 2), respectively. The third pad 1311 numbered 1 is connected to the first positive pad (R+) through an interconnection region 12, and the third pad 1311 numbered 2 is connected to the first negative pad (R−) through an interconnection region 12.

A plurality of first-type laser chips 221 and a plurality of second-type laser chips 222 are packaged in the second package 212. The first-type laser chips 221 are electrically connected to two corresponding second pads 241 through connection wires 23 inside the second package 212, and the two second pads 241 are connected to two corresponding third pads 1311 (i.e., the third pads 1311 numbered 5 and 6), respectively. The third pad 1311 numbered 5 is connected to the second negative pad (B−) through an interconnection region 12, and the third pad 1311 numbered 6 is connected to the second positive pad (B+) through an interconnection region 12. The second-type laser chips 222 are electrically connected to two corresponding second pads 241 through connection wires 23 inside the second package 212, and the two second pads 241 are connected to two corresponding third pads 1311 (i.e., the third pads 1311 numbered 7 and 8), respectively. The third pad 1311 numbered 7 is connected to the third positive pad (G+) through an interconnection region 12, and the third pad 1311 numbered 8 is connected to the third negative pad (G−) through an interconnection region 12.

The third pads 1311 numbered 3, 4 and 5 may have a plurality of connection manners based on the structure described above.

In some embodiments, as shown in FIGS. 21 and 28, due to the limitation of wiring space and the addition of the temperature-measuring component 4, if traces are disposed between the third pad 1311 (e.g., the third pad 1311 numbered 5) and the second negative pad (B−), areas of other traces will be reduced, or the traces overlap with the temperature-measuring component 4, resulting in a short circuit. Therefore, the third pads 1311 numbered 3, 4 and 5 may be electrically connected to the second negative pad (B−) through the same interconnection region 12. For example, the second negative pad (B−) is connected to three third pads 1311 numbered 3, 4 and 5 through a corresponding interconnection region 12. In this way, in an aspect, the wiring width may be increased, to improve the electric current carrying capacity, thereby improving the luminous intensity of the laser chips 203; in another aspect, it is also possible to avoid affecting the positions of the temperature-measuring component 4 and the first pads 11, thereby simplifying the structure of the light-emitting device 2000.

In some embodiments, as shown in FIG. 29, the third pads 1311 numbered 4 and 5 are electrically connected to the second negative pad (B−) through the same interconnection region 12. The third pad 1311 numbered 5 is correspondingly connected to a second pad 241 at the bottom of the second package 212, and the second pad 241 is connected to a negative electrode of the blue laser chips, thereby achieving the electrical connection between the blue laser chips and the second negative pad (B−). In this case, the third pads 1311 numbered 2 and 3 are electrically connected to the first negative pad (R−) through the same interconnection region 12. The third pad 1311 numbered 2 is connected to a second pad 241 at the bottom of the first package 211, and the second pad 241 is connected to a negative electrode of the red laser chips, thereby achieving the electrical connection between the red laser chips and the first negative pad (R−). In this way, wiring widths of the first negative pad (R−) and the second negative pad (B−) may be doubled, to improve the electric current carrying capacity, thereby improving the luminous intensity of the laser chips 203. It is also possible to avoid affecting the positions of the temperature-measuring component 4 and the first pads 11, thereby simplifying the structure of the light-emitting device 2000.

In some embodiments, considering the orientation shown in FIG. 28 or 29 as an example, with the position of the temperature-measuring component 4 as a dividing line, the first positive pad (R+) and the first negative pad (R−) may be disposed on a left side of the temperature-measuring component 4; the second negative pad (B−), the second positive pad (B+), the third positive pad (G+) and the third negative pad (G−) may be disposed on a right side of the temperature-measuring component 4. Correspondingly, the positions of the plurality of third pads 1311 correspond to the positions of the plurality of second pads 241, respectively, so as to ensure uniform wiring width.

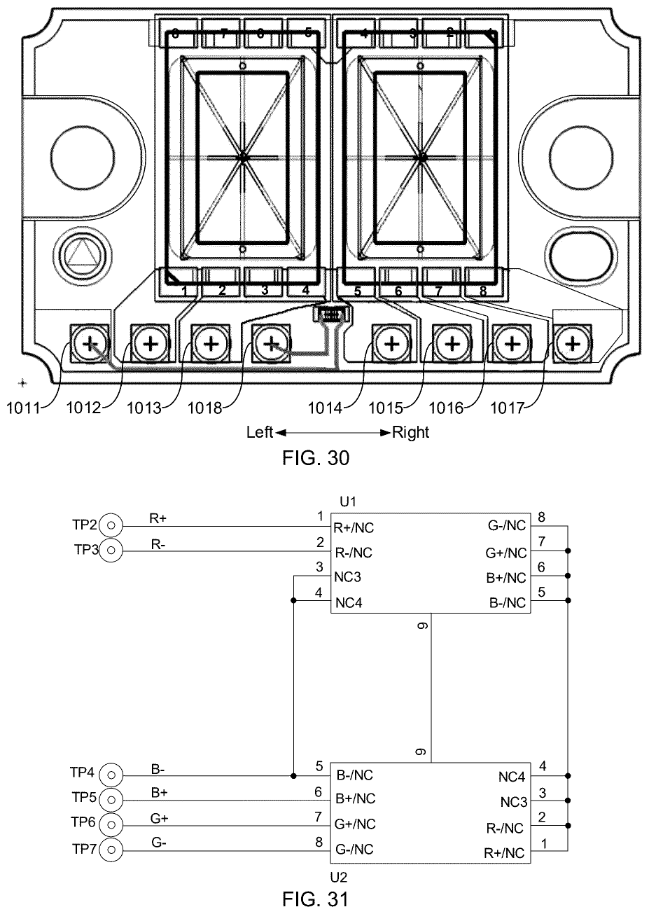

For example, as shown in FIG. 30, the fourth positive pad (NTC+) and the fourth negative pad (NTC−) may be disposed on the left side of the temperature-measuring component 4. In this way, a second pad 241 of any package 202 may be directly electrically connected to the first pad 11 adjacent to the second pad 241, but the traces between the first pads 11 and the temperature-measuring component 4 need to be readjusted. For example, space is required to be increased on a lower side (e.g., a portion of the substrate 100 located on a side of the plurality of first pads 11 away from the packages 202) of the substrate 100, to accommodate the traces between the first pads 11 and the temperature-measuring component 4; alternatively, the fourth positive pad (NTC+) and the fourth negative pad (NTC−) may also be disposed on the left and right sides of the temperature-measuring component 4, respectively, and in this case, the first pads 11 are present in different numbers on the two sides of the temperature-measuring component 4.

In some embodiments, if there is no need to consider the space requirement of the temperature-measuring component 4, the third pads 1311 corresponding to any type of laser chip 203 may correspond to the positions of the second pads 241 of the package 202 and be evenly distributed, and the present disclosure is not limited thereto.

For example, as shown in FIG. 31, FIG. 31 is the circuit diagram corresponding to the light-emitting device 2000 shown in FIG. 21 or 28, U1 denotes the first package 211, and U2 denotes the second package 212. The first package 211 and the second package 212 have the same structure, and U2 is obtained by rotating U1 clockwise by 180°. The pin 1 of U1 is connected to TP2, the pin 2 of U1 is connected to TP3, the pins 3 and 4 of U1 and the pin 5 of U2 are connected to TP4, the pin 6 of U2 is connected to TP5, the pin 7 of U2 is connected to TP6, and the pin 8 of U2 is connected to TP7. The pins 1 to 4 of U1 correspond to the four third pads 1311 numbered 1 to 4, respectively, and the pins 5 to 8 of U2 correspond to the four third pads 1311 numbered 5 to 8, respectively. TP2 corresponds to the first positive pad (R+), TP3 corresponds to the first negative pad (R−), TP4 corresponds to the second negative pad (B−), TP5 corresponds to the second positive pad (B+), TP6 corresponds to the third positive pad (G+), and TP7 corresponds to the third negative pad (G−).

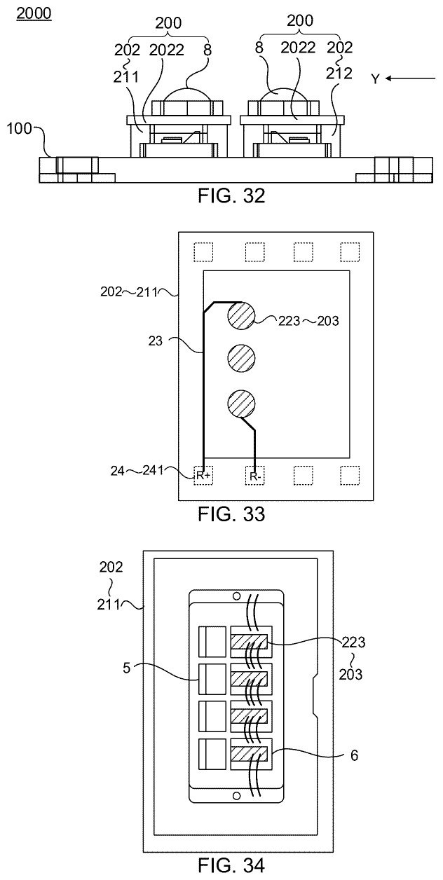

In some embodiments, as shown in FIG. 32, in a case where at least one package 202 includes the first package 211 and the second package 212, the first package 211 and the second package 212 may be arranged along a direction Y. The light-emitting assembly 200 further includes a lens 8 (e.g., the collimating portion 201). The lens 8 is located on a side of the package 202 away from the substrate 100. A laser chip 203 and a reflecting prism 5 (e.g., the light deflecting component 204) are disposed in each of the first package 211 and the second package 212. The laser chip 203 emits laser beam in the direction Y or an opposite direction of the direction Y. The laser beam is incident on a reflecting surface of the reflecting prism and reflected by the reflecting prism. The reflected laser beam passes through at least one of an optical window (e.g., the sealing glass) and the lens 8 and exits from the light-emitting assembly 200. Herein, the direction Y is a direction from right to left in FIG. 26.

In some embodiments, as shown in FIG. 32, the light-emitting assembly 200 may further include at least one cover plate 2022 (e.g., the optical window or sealing glass). The cover plate may also be referred to as a light-transmissive glass sealing member. The light-transmissive glass sealing member is located on the side of the package 202 away from the substrate 100. The package 202 and the light-transmissive glass sealing member form an accommodating space, and the accommodating space accommodates at least one type of the plurality of types of laser chips.

In some other embodiments, the light-emitting device 1000 may further include other components known to those skilled in the art, such as the heat sink 6, and the present disclosure is not limited thereto.

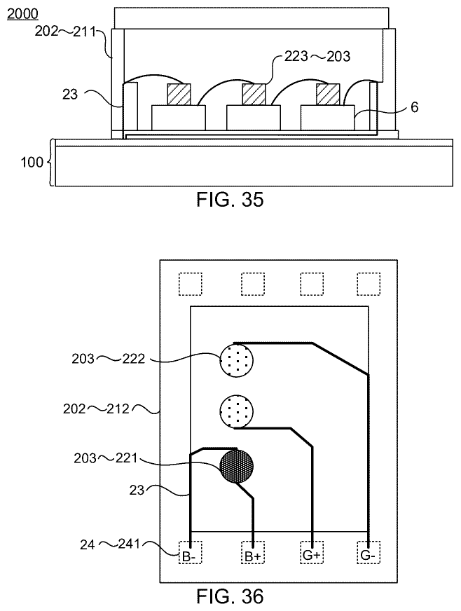

As shown in FIGS. 33 to 35, a plurality of third-type laser chips 223 are disposed in the first package 211. The plurality of third-type laser chips 223 are connected in series. The negative and positive electrodes of the plurality of third-type laser chips 223 are connected to the second pads 241 disposed at the bottom of the first package 211 through the wires (e.g., the connection wires 23) inside the first package 211, respectively. The second pads 241 are electrically connected to the third pads 1311 of the substrate 100, and the third pads 1311 are electrically connected to the first pads 11 through interconnection regions 12. In this way, the electrical connection between the third-type laser chips and the substrate 100 is achieved. The wires inside the first package 211 may be located inside at least one of the side wall and the bottom wall of the package 202.

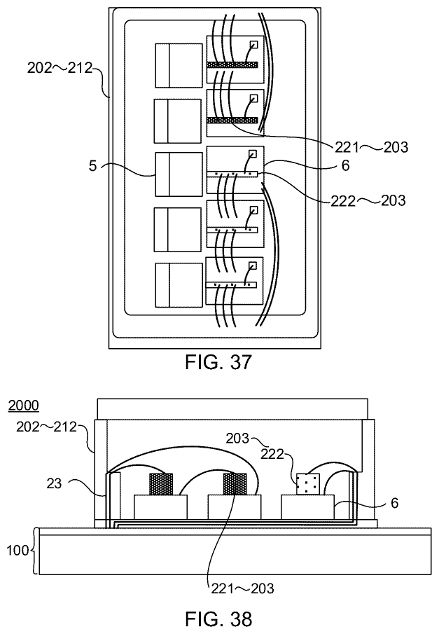

As shown in FIGS. 36 to 38, a plurality of first-type laser chips 221 and a plurality of second-type laser chips 222 are disposed in the second package 212. The plurality of first-type laser chips 221 are connected in series, and the plurality of second-type laser chips 222 are connected in series. The series circuit of the plurality of first-type laser chips 221 is independent of the series circuit of the plurality of second-type laser chips 222. The positive and negative electrodes of the first-type laser chips 221 are electrically connected to the second pads 241 at the bottom of the second package 212 through the wires inside the second package 212, respectively. The second pads 241 are electrically connected to the third pads 1311 of the substrate 100, and the third pads 1311 are electrically connected to the corresponding first pads 11 through interconnection regions 12. The positive and negative electrodes of the second-type laser chip 222 are electrically connected to the second pads 241 at the bottom of the second package 212 through the wires inside the second package 212, respectively. The second pads 241 are electrically connected to the third pads 1311 of the substrate 100, and the third pads 1311 are connected to the corresponding first pads 11 through interconnection regions 12. In this way, the electrical connection between the first-type laser chips 221 and the substrate 100, and the electrical connection between the second-type laser chips 222 and the substrate 100 may be achieved. The wires (e.g., the connection wires 23) inside the second package 212 are located inside at least one of the side wall and bottom wall of the package 202.

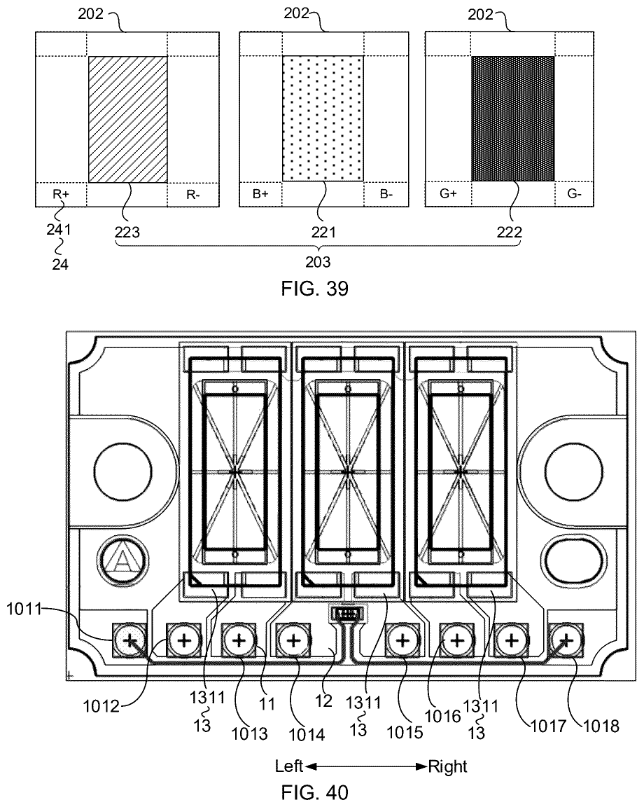

In some embodiments, as shown in FIGS. 39 to 41, any one of the packages 202 is provided with a type of laser chip 203, and an arrangement direction of the plurality of packages 202 is the same as an arrangement direction of the plurality of first pads 11. On a side of any one of the packages 202 facing the substrate 100 is provided with at least two second pads 241 arranged side by side, the at least two second pads 241 are disposed proximate to the first pads 11 and connected to a group of first pads 11.

In some examples, the light-emitting device 2000 includes three packages 202, and any type of laser chip 203 is individually packaged in a package 202. That is to say, a plurality of laser chips 203 in a package 202 emit laser beams of the same color and are connected in series. For example, all the first-type laser chips 221 are disposed in the same package 202 and are connected in series; all the second-type laser chips 222 are disposed in the same package 202 and are connected in series; all the third-type laser chips 223 are disposed in the same package 202 and are connected in series. The plurality of first pads 11 are located on the same side of the three packages 202, and the plurality of first pads 11 and the plurality of packages 202 are arranged in the same direction. Any one of the packages 202 is provided with two second pads 241 proximate to the first pads 11, and an arrangement direction of the two second pads 241 is the same as the arrangement direction of the plurality of first pads 11. The two second pads 241 of any package 202 are electrically connected to a corresponding group of first pads 11.

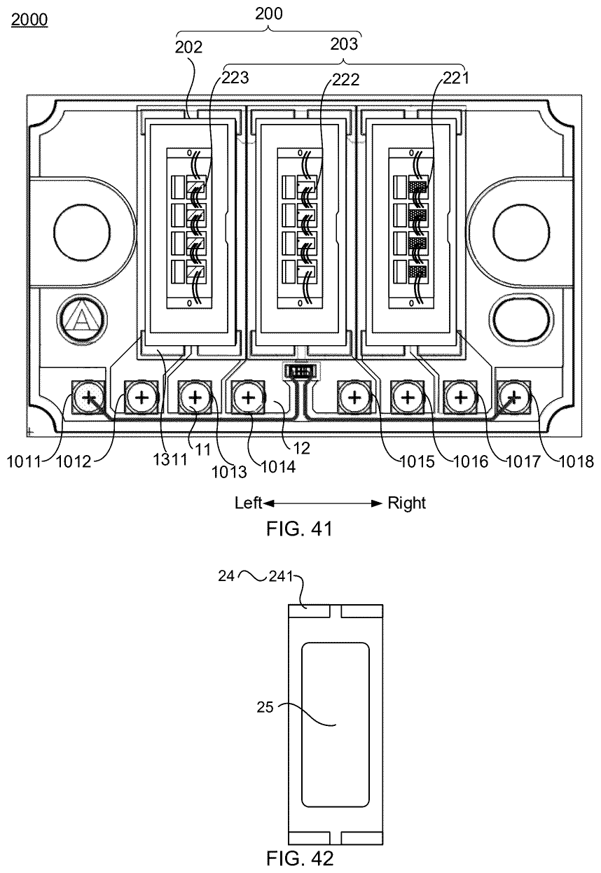

In this case, as shown in FIGS. 40 and 41, the substrate 100 includes three connection patterns 13 corresponding to the three packages 202. Each connection pattern 13 includes two third pads 1311, and the two third pads 1311 are proximate to the plurality of groups of first pads 11 and are arranged side by side. Each third pad 1311 is electrically connected to a corresponding first pad 11 through an interconnection region 12. The two third pads 1311 are connected to the plurality of second pads 241 (as shown in FIG. 42) of the package 202, respectively. The second pads 241 are electrically connected to the laser chips 203 located in the package 202 through the connection wires 23, thereby achieving the electrical connection between the laser chips 203 and the corresponding first pads 11.

For example, as shown in FIGS. 40 and 41, the left package 202 among the three packages 202 is used for packaging the red laser chips, and the two second pads 241 corresponding to the package 202 are connected to the first positive pad (R+) and the first negative pad (R−) through the third pads 1311 and the interconnection regions 12, respectively. The middle package 202 among the three packages 202 is used for packaging the blue laser chips, and the two second pads 241 corresponding to the package 202 are connected to the second negative pad (B−) and the second positive pad (B+) through the third pads 1311 and the interconnection regions 12, respectively. The right package 202 among the three packages 202 is used for packaging the green laser chips, and the two second pads 241 corresponding to the package 202 are connected to the third positive pad (G+) and the third negative pad (G−) through the third pads 1311 and the interconnection regions 12, respectively.

In some other embodiments, as shown in FIG. 42, a first portion of the plurality of second pads 241 on the package 202 may be disposed proximate to the first pads 11, and a second portion of the plurality of second pads 241 on the package 202 may be disposed away from the first pads 11. Correspondingly, a first portion of the plurality of third pads 1311 disposed on the substrate body may be disposed proximate to the first pads 11, and a second portion of the plurality of third pads 1311 disposed on the substrate body may be disposed away from the first pads 11. In a case where the distance between the positioning hole and the package 202 and the distance between the plurality of packages 202 satisfy the minimum wiring width, the interconnection regions 12 may be disposed between the positioning hole and the package 202, between the plurality of packages 202, or between the positioning hole and the package 202 and between the plurality of packages 202. In this way, the plurality of third pads 1311 away from the first pads 11 may be electrically connected to the plurality of third pads 1311 proximate to the first pads 11, thereby increasing the wiring width and improving the electric current carrying capacity.

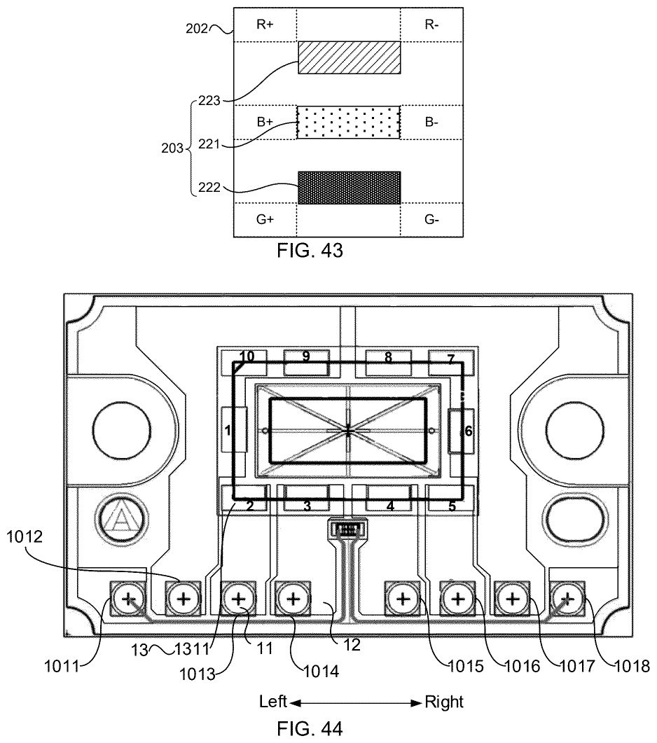

In some embodiments, as shown in FIGS. 43 to 45, in a case where at least one package 202 includes a package 202, three types of laser chips 203 (i.e., the first-type laser chip 221, the second-type laser chip 222, and the third-type laser chip 223) may be disposed in the package 202. The package 202 is provided with six second pads 241. Four of the six second pads 241 are arranged side by side and disposed proximate to a first side of the package 202, and the first side is a side of the package 202 proximate to the first pads 11. Two of the six second pads 241 are disposed proximate to a second side and a third side of the package 202 that are adjacent to the first side, respectively. The second side and the third side are arranged opposite to each other. The six second pads 241 of the package 202 are correspondingly connected to three groups of first pads 11.

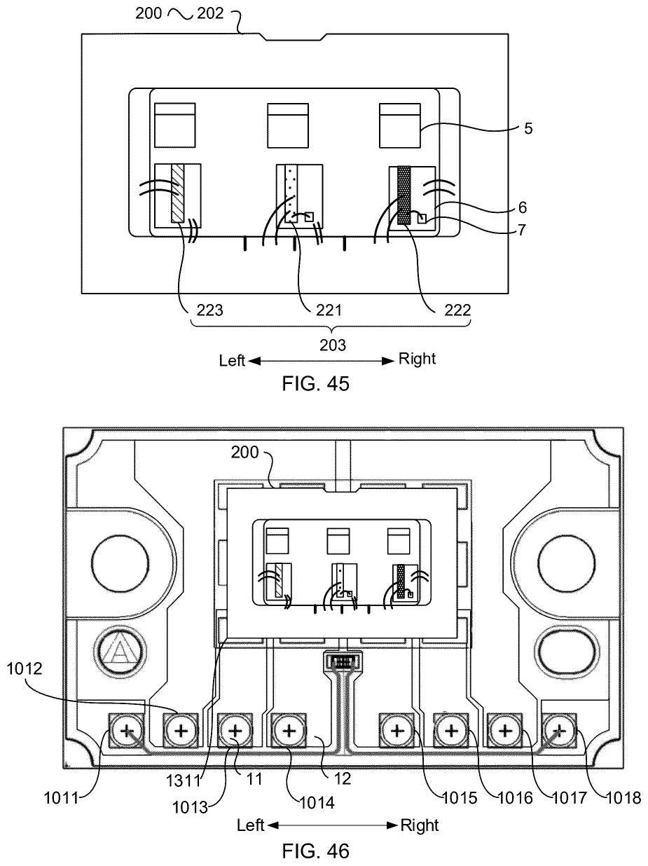

For example, as shown in FIG. 45, the first-type laser chips 221, the second-type laser chips 222 and the third-type laser chips 223 are located in the same package 202. The three types of laser chips 203 are arranged from left to right and are electrically connected to the wires (e.g., the connection wires 23) inside the package 202 through wires. For example, the third-type laser chips 223 are red laser chips, the first-type laser chips 221 are blue laser chips, and the second-type laser chips 222 are green laser chips.

As shown in FIG. 45, the light-emitting assembly 200 further includes a plurality of anti-static components 7. The blue and green laser chips require the anti-static components 7, while the materials of the red laser chips have strong anti-static properties, so that no anti-static component 7 is required for the red laser chips.

It will be noted that, as shown in FIG. 45, the light-emitting assembly 200 further includes a plurality of reflecting prisms 5 and a plurality of heat sinks 6. The plurality of laser chips 203 and the plurality of anti-static components 7 are disposed on sides of the heat sinks 6 away from the substrate 100. The plurality of reflecting prisms 5 are located on laser-exit sides of the plurality of laser chips 203, and reflecting surfaces of the plurality of reflecting prisms 5 are aligned with the plurality of laser chips 203. The plurality of laser chips 203 may be disposed in one-to-one correspondence with the plurality of heat sinks 6, or the plurality of laser chips 203 emitting laser beams of the same color may be disposed on the same heat sink 6, and the present disclosure is not limited thereto.

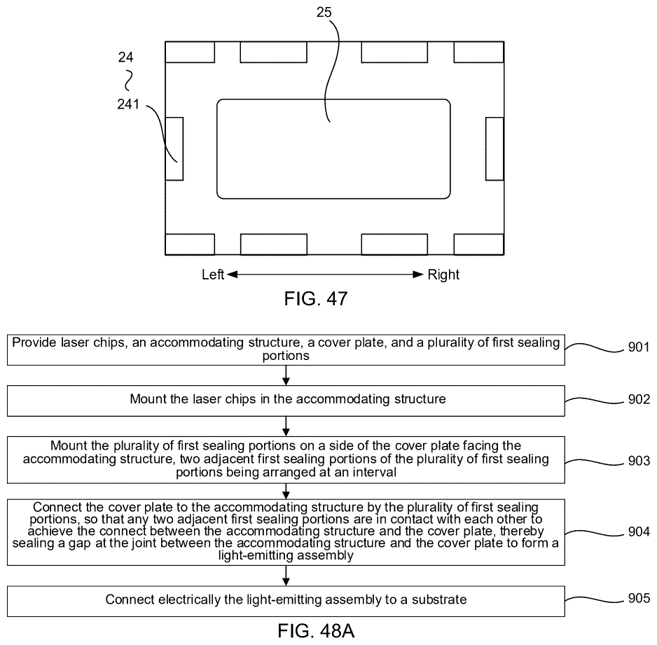

As shown in FIGS. 46 and 47, a side of the package 202 proximate to the first pads 11 is the first side. The second side and the third side of the package 202 are located on the left and right sides of the first side, respectively, and are adjacent to the first side. The package 202 is provided with six second pads 241. Four of the six second pads 241 are arranged side by side and disposed proximate to the first side of the package 202, and two of the six second pads 241 are disposed proximate to the second side and the third side of the package 202, respectively.

Correspondingly, as shown in FIG. 44, a side (corresponding to the first side of the package 202) of the connection pattern 13 proximate to the first pads 11 is provided with four third pads 1311, and a third pad 1311 is disposed on each of the left and right sides (corresponding to the second and third sides of the package 202) of the four third pads 1311. The six third pads 1311 are connected to the six second pads 241, respectively, and the six third pads 1311 are electrically connected to the corresponding first pads 11 through the interconnection regions 12, respectively, thereby achieving the corresponding connection between the six second pads 241 and the six first pads 11.

The connection relationship between the six second pads 241 and the six first pads 11 is as follows.

As shown in FIGS. 44 and 47, the second pad 241 proximate to the second side (e.g., the left side of the package 202) is electrically connected to the third pad 1311 numbered 1. The third pad 1311 numbered 1 is electrically connected to the first positive pad (R+) through an interconnection region 12. In this case, at least one of the third pads 1311 numbered 9 and 10 and the third pad 1311 numbered 1 may be electrically connected to the first positive pad (R+) through the same interconnection region 12.

The first one of the second pads 241 at a left end of the first side is electrically connected to the third pad 1311 numbered 2, and the third pad 1311 numbered 2 is electrically connected to the first negative pad (R−) through an interconnection region 12. The second one of the second pads 241 at the left end of the first side is electrically connected to the third pad 1311 numbered 3, and the third pad 1311 numbered 3 is electrically connected to the second negative pad (B−) through an interconnection region 12. The second one of the second pads 241 at a right end of the first side is electrically connected to the third pad 1311 numbered 4, and the third pad 1311 numbered 4 is electrically connected to the second positive pad (B+) through an interconnection region 12. The first one of the second pads 241 at the right end of the first side is electrically connected to the third pad 1311 numbered 5, and the third pad 1311 numbered 5 is electrically connected to the third positive pad (G+) through an interconnection region 12.

The second pad 241 proximate to the third side is electrically connected to the third pad 1311 numbered 6, and the third pad 1311 numbered 6 is electrically connected to the third negative pad (G−) through an interconnection region 12. In this case, at least one of the third pads 1311 numbered 7 and 8, and the third pad 1311 numbered 6, may be electrically connected to the third negative pad (G−) through the same interconnection region 12.

Of course, in some other embodiments, the first positive pad (R+) may also be connected to at least one of the third pads 1311 numbered 1, 10 and 9 through an interconnection region 12; similarly, the third negative pad (G−) may be connected to at least one of the third pads 1311 numbered 6, 7 and 8 through an interconnection region 12. The structure described above may be configured according to the relative positions and sizes of the substrate 100, the package 202 and the positioning holes, and the present disclosure is not limited thereto.

In some embodiments, as shown in FIGS. 46 and 47, the package 202 is provided with four second pads 241 proximate to a fourth side of the package 202, the four second pads 241 are arranged side by side, and the fourth side is opposite to the first side. Two of the four second pads 241 are connected to two corresponding third pads 1311, respectively. The two third pads 1311 are connected to a third pad 1311 through the same interconnection region 12, and the third pad 1311 is connected to the second pad 241 proximate to the second side. Another two of the four second pads 241 are connected to two corresponding third pads 1311, respectively. The two third pads 1311 are connected to a third pad 1311 through the same interconnection region 12, and the third pad 1311 is connected to the second pad 241 proximate to the third side.

The fourth side of the package 202 is a side of the package 202 away from the first pads 11, and four second pads 241 are disposed proximate to the fourth side. Correspondingly, as shown in FIG. 44, the connection pattern 13 further includes four third pads 1311 (e.g., the third pads 1311 numbered 7, 8, 9 and 10). The four third pads 1311 are away from the first pads 11, and electrically connected to the four second pads 241 proximate to the fourth side, respectively.

The two third pads 1311 numbered 9 and 10 are electrically connected to an adjacent third pad 1311 (i.e., the third pad 1311 numbered 1) located on the left side of the connection pattern 13, so that the three third pads 1311 numbered 1, 9 and 10 are electrically connected to the first positive pad (R+) through the same interconnection region 12, thereby enabling two second pads 241 proximate to the fourth side of the package 202 to be connected to the second pad 241 proximate to the second side of the package 202 through the same interconnection region 12. The two third pads 1311 numbered 7 and 8 are connected to an adjacent third pad 1311 (i.e., the third pad 1311 numbered 6) located on the right side of the connection pattern 13, so that the three third pads 1311 numbered 6, 7 and 8 are electrically connected to the third negative pad (G−) through the same interconnection region 12, thereby enabling another two second pads 241 proximate to the fourth side of the package 202 to be connected to the second pad 241 proximate to the third side of the package 202 through the same interconnection region 12.

In this way, each of the first positive pad (R+) and the third negative pad (G−) is connected to three third pads 1311, which may increase the width of the interconnection region 12 and help improve the electric current carrying capacity.

It will be noted that FIGS. 44 and 46 illustrate by considering only an example in which the plurality of third pads 1311 away from the first pads 11 are grouped in pairs, that is, the third pads 1311 numbered 9 and 10 are in one group, and the third pads 1311 numbered 7 and 8 are in another group. Moreover, the third pads 1311 numbered 9 and 10 are electrically connected to the third pad 1311 numbered 1, and the third pads 1311 numbered 7 and 8 are electrically connected to the third pad 1311 numbered 6. However, this does not constitute a limitation on the light-emitting device 2000.

In some other embodiments, at least one of the four third pads 1311 (i.e., the third pads 1311 numbered 7, 8, 9 and 10) corresponding to the fourth side of the package 202 may also be electrically connected to the third pad 1311 numbered 1, and at least one of the remaining third pads 1311 of the four third pads 1311 may also be electrically connected to the third pad 1311 numbered 6. For example, the third pads 1311 numbered 8, 9, and 10 are electrically connected to the third pad 1311 numbered 1, and the third pad 1311 numbered 7 is electrically connected to the third pad 1311 numbered 6; alternatively, the third pad 1311 numbered 10 is electrically connected to the third pad 1311 numbered 1, and the third pads 1311 numbered 7, 8, and 9 are electrically connected to the third pad 1311 numbered 6; alternatively, the third pads 1311 numbered 7, 8, 9, and 10 are electrically connected to the third pad 1311 numbered 1; alternatively, the third pads 1311 numbered 7, 8, 9, and 10 are electrically connected to the third pad 1311 numbered 6, and the present disclosure is not limited thereto.

In some embodiments, a single-side width of the first pad 11 on the plane where the substrate 100 is located is any value within a range of 1.3 mm to 1.7 mm, inclusive. For example, the single-side width of the first pad 11 is 1.3 mm, 1.4 mm, 1.5 mm, 1.6 mm or 1.7 mm. In the arrangement direction of the plurality of first pads 11, a distance between two adjacent first pads 11 is any value within a range of 0.8 mm to 1.2 mm, inclusive. For example, the distance between two adjacent first pads 11 is 0.8 mm, 0.9 mm, 1.0 mm, 1.1 mm or 1.2 mm. Herein, the single-side width refers to a distance from a reference line (e.g., a center line or reference plane) of a structure to a boundary of a single side.

In some embodiments, a lengthwise side width of the third pad 1311 on the plane where the substrate 100 is located is any value within a range of 1.1 mm to 1.5 mm, inclusive. For example, the lengthwise side width of the third pad 1311 is 1.1 mm, 1.2 mm, 1.3 mm, 1.4 mm or 1.5 mm. A widthwise width of the third pad 1311 is any value within a range of 0.4 mm to 0.8 mm, inclusive. For example, the widthwise side width of the third pad 1311 is 0.4 mm, 0.5 mm, 0.6 mm, 0.7 mm or 0.8 mm. In the arrangement direction of the plurality of third pads 1311, a distance between two adjacent third pads 1311 is any value within a range of 0.1 mm to 0.5 mm, inclusive. For example, the distance between two adjacent third pads 1311 is 0.1 mm, 0.2 mm, 0.3 mm, 0.4 mm, or 0.5 mm.

The present disclosure does not limit the size (e.g., the length and width of the package 202) of the package 202, and the size of the package 202 may be set according to the requirements of the light-emitting device 2000. For example, the package 202 has dimensions of 10.6 mm in length and 6.4 mm in width.

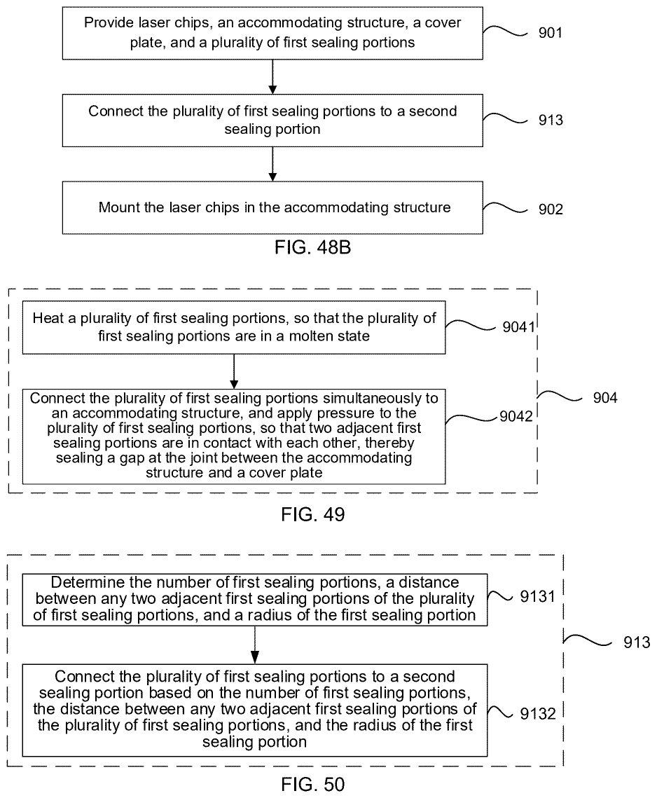

A manufacturing method of a light-emitting device is further provided in some embodiments of the present disclosure, and the method may be applied to fabrication of the light-emitting device 2000 in any one of the embodiments described above. FIG. 48A is a flow chart of a manufacturing method of a light-emitting device, in accordance with some embodiments. As shown in FIG. 48A, the method includes steps 901 to 905.

In step 901, laser chips, an accommodating structure, a cover plate, and a plurality of first sealing portions are provided.

In step 902, the laser chips are mounted in the accommodating structure.

In step 903, the plurality of first sealing portions are mounted on a side of the cover plate facing the accommodating structure, and two adjacent first sealing portions of the plurality of first sealing portions are arranged at an interval.

In step 904, the cover plate is connected to the accommodating structure by the plurality of first sealing portions, so that any two adjacent first sealing portions are in contact with each other to achieve the connect between the accommodating structure and the cover plate, thereby sealing a gap at the joint between the accommodating structure and the cover plate to form a light-emitting assembly.

In step 905, the light-emitting assembly is electrically connected to a substrate.

In some embodiments, the method further includes the following step: a second sealing portion is disposed on the side of the cover plate facing the accommodating structure before the plurality of first sealing portions are disposed on the cover plate.

FIG. 48B is another flow chart of a manufacturing method of a light-emitting device, in accordance with some embodiments. In some embodiments, as shown in FIG. 48B, the method further includes a step 913.

In step 913, the plurality of first sealing portions are connected to the second sealing portion.

FIG. 49 is yet another flow chart of a manufacturing method of a light-emitting device, in accordance with some embodiments. In some embodiments, as shown in FIG. 49, the step 904 includes steps 9041 and 9042.

In step 9041, the plurality of first sealing portions are heated, so that the plurality of first sealing portions are in a molten state.

In step 9042, the plurality of first sealing portions are simultaneously connected to the accommodating structure, and pressure is applied to the plurality of first sealing portions, so that two adjacent first sealing portions are in contact with each other, thereby sealing the gap at the joint between the accommodating structure and the cover plate.

FIG. 50 is yet another flow chart of a manufacturing method of a light-emitting device, in accordance with some embodiments. In some embodiments, as shown in FIG. 50, the step 913 includes steps 9131 and 9132.

In step 9131, the number of first sealing portions, a distance between any two adjacent first sealing portions of the plurality of first sealing portions, and a radius of the first sealing portion are determined.

In step 9132, the plurality of first sealing portions are connected to the second sealing portion based on the number of first sealing portions, the distance between any two adjacent first sealing portions of the plurality of first sealing portions, and the radius of the first sealing portion.

For the detailed description of the structures and connection methods of the first sealing portions, the second sealing portion, the laser chips, the accommodating structure, and the cover plate, reference may be made to the relevant content of the light-emitting device 2000 described above, and details will not be repeated herein.

The manufacturing process and operating principle of the light-emitting device provided in some embodiments of the present disclosure are described below by way of example with reference to the accompanying drawings. It will be noted that the manufacturing methods in some embodiments of the present disclosure are merely examples, and the steps of some methods may be rearranged interchangeably. In the manufacturing methods in some embodiments of the present disclosure, the manufacturing process of all potential components of the light-emitting device may not be described in detail, and components for which no examples are provided will be regarded as not being elaborated for the sake of conciseness in description.

First, laser chips 203, an accommodating structure 2021, a cover plate 2022, a plurality of first sealing portions 2023 and a second sealing portion 2024 are provided.

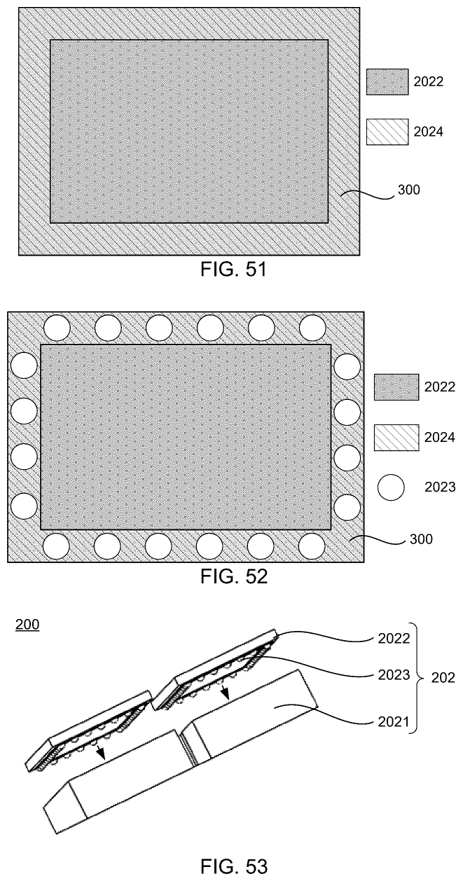

FIG. 51 is a diagram showing a structure of a cover plate and a second sealing portion, in accordance with some embodiments. As shown in FIG. 51, the second sealing portion 2024 is disposed within a corresponding second sealing region on a side of the cover plate 2022 facing the accommodating structure 2021. The second sealing portion 2024 may be used to connect the first sealing portions 2023. For example, a metallization layer is formed within the second sealing region. The cover plate 2022 is used to be connected with the accommodating structure 2021, to form a package 202, thereby achieving the sealing for the laser chips in the package 202. The cover plate 2022 may be made of high-strength sapphire, quartz, or glass. The second sealing portion 2024 is disposed around the cover plate 2022, and the remaining region of the cover plate 2022 is a light-transmissive region. The high airtightness may be achieved by combining the second sealing portion 2024 with the first sealing portions 2023.

FIG. 52 is a diagram showing a structure of a cover plate, a plurality of first sealing portions and a second sealing portion, in accordance with some embodiments. As shown in FIG. 52, the number of first sealing portions 2023, a distance between any two adjacent first sealing portions 2023 of the plurality of first sealing portions 2023, and a radius of the first sealing portion 2023 are determined based on the size of the package 202. Moreover, the plurality of first sealing portions 2023 are connected to the second sealing portion 2024 based on the number of first sealing portions 2023, the distance between any two adjacent first sealing portions 2023 of the plurality of first sealing portions 2023, and the radius of the first sealing portion 2023.

Then, as shown in FIG. 13, the laser chips 203, the light deflecting components 204, the heat sinks and other components or structures are disposed in the accommodating structure 2021. The laser chip 203 is configured to emit a laser beam, and the light deflecting component 204 is configured to change a direction of the laser beam. For example, the light deflecting component 204 is a reflecting prism. The heat sink is configured to conduct heat generated by the laser chip 203 for heat dissipation.

FIG. 53 is a diagram showing another structure of a light-emitting assembly, in accordance with some embodiments. As shown in FIG. 53, the fabricated cover plate 2022 is aligned with the accommodating structure 2021, and the cover plate 2022 is covered on the accommodating structure 2021. Then, the first sealing portions 2023 are heated, and pressure is applied to the cover plate 2022, so that shapes of the plurality of first sealing portions 2023 are changed due to the action of pressure and fill the sealing region 300, thereby completing the sealing between the cover plate 2022 and the accommodating structure 2021.

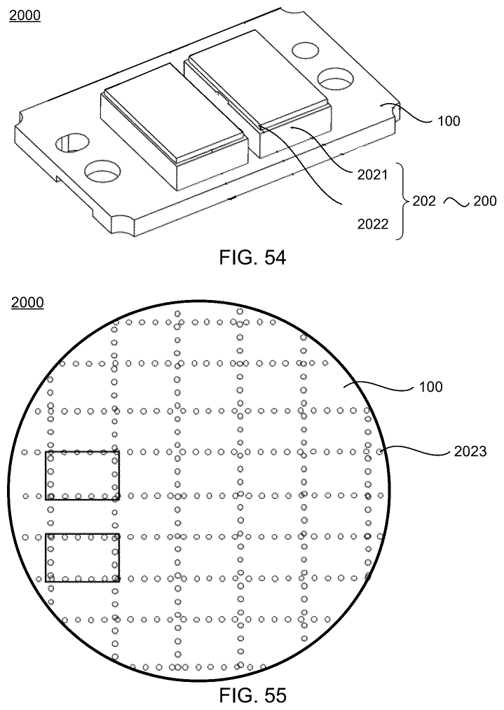

FIG. 54 is a diagram showing yet another structure of a light-emitting device, in accordance with some embodiments. As shown in FIG. 54, the light-emitting assembly 200 is electrically connected to the substrate 100 to complete the fabrication of the light-emitting device 2000. The substrate 100 may not only be used to fix the light-emitting assembly 200, but also have a printed circuit board (PCB) disposed therein, so that the circuit of the substrate 100 is connected to the circuit of the package 202, thereby achieving the electrical connection between the substrate 100 and the laser chips 203. The package 202 may be fixed to the substrate 100 with a tin-silver-copper alloy by means of reflow soldering. Alternatively, the package 202 may be fixed to the substrate 100 by means of the sintering of silver paste or copper paste at high temperature and at pressure. The substrate 100 may be made of metal materials such as oxygen-free copper or electrolytic copper.

In some embodiments, the first sealing portions 2023 may be prefabricated on a large scale on a base material corresponding to the cover plates 2022. FIG. 55 is a diagram showing a structure of cover plates, in accordance with some embodiments. As shown in FIG. 55, the transmittance of the cover plate 2022 is increased by providing a light-transmissive film layer, and the second sealing portions 2024 are formed on the cover plates 2022 by means of metallization sputtering. Then, the first sealing portions 2023 are fabricated on the second sealing portions 2024. The cover plates 2022 are further cut to shape after all the processes are completed (i.e., the connections between the cover plates 2022 and the accommodating structures 2021 are completed). The metallization sputtering is a common surface coating technology that may form a metal film on a surface of a material and is achieved through a physical sputtering process.

In the description of the embodiments described above, specific features, structures, materials, or characteristics may be combined in a suitable manner in any one or more embodiments or examples.

It will be noted that any one of the disclosed technical solutions in the present disclosure may, to a certain extent, solve one or more of the technical problems described above and achieve the corresponding technical effects. Alternatively, a plurality of disclosed technical solutions may also be combined into an overall solution, so as to solve one or more of the technical problems described above and achieve the corresponding technical effects. Alternatively, some disclosed technical solutions may also be combined into an overall solution, while adopting the related art and deteriorated solutions, but the solutions may compensate the deterioration trend through the technical means in the present disclosure, so that on the whole, one or more of the technical problems described above may be solved to a certain extent and the corresponding technical effects may be achieved. Alternatively, each of the disclosed technical solutions is combined into a complete technical solution, constituting an organic and indivisible overall solution, thereby solving the technical problems as a whole and achieves the corresponding technical effects.

Any disclosed technical solution in the present disclosure and the recombination of the plurality of disclosed technical solutions each may form a complete technical solution and solve one or more of the technical problems described above and achieve the corresponding technical effects. They all belong to the content of the present disclosure and belong to the content that is directly and unambiguously determined according to the content of the present disclosure.

A person skilled in the art will understand that the scope of disclosure in the present disclosure is not limited to specific embodiments described above and may modify and substitute some elements of the embodiments without departing from the spirits of the present disclosure. The scope of the present disclosure is limited by the appended claims.

What is claimed is:

1. A light-emitting device, comprising:
a substrate, comprising:
a substrate body;
at least one connection pattern, disposed on the substrate body and including a conductive portion;
a plurality of interconnection regions, disposed on the substrate body; and
a plurality of groups of first pads, disposed on the substrate body, the plurality of groups of first pads being electrically connected to the conductive portion through the plurality of interconnection regions, and any one group of the plurality of groups of first pads includes two first pads with different polarities; and
a light-emitting assembly, disposed on the at least one connection pattern, and including:
at least one package, at least one of a side wall and bottom wall of the at least one package being provided with connection wires;
a conductive structure, disposed on a side of the at least one package facing the substrate and electrically connected to the connection wires and the conductive portion; and
a plurality of types of laser chips, disposed in the at least one package and electrically connected to the connection wires, the plurality of types of laser chips being configured to emit at least two types of laser beams of different colors, laser chips of a same type of the plurality of types of laser chips being electrically connected to the any one group of first pads.

2. The light-emitting device according to claim 1, wherein the at least one connection pattern is disposed on a surface of the substrate body facing the light-emitting assembly; the plurality of interconnection regions include a plurality of connection traces, the plurality of connection traces are disposed inside the substrate body; in a direction perpendicular to a plane where the substrate is located, any one first pad of the plurality of groups of first pads at least partially overlaps with any one of the plurality of interconnection regions, the conductive portion at least partially overlaps with the plurality of interconnection regions, and the conductive structure at least partially overlaps with the conductive portion.

3. The light-emitting device according to claim 1, wherein any one type of the plurality of types of laser chips includes a plurality of laser chips, the plurality of laser chips of the same type are connected in series to constitute a series circuit, and two ends of the series circuit are electrically connected to two first pads of a corresponding group of first pads, respectively; a number of a plurality of first pads of the plurality of groups of first pads electrically connected to the light-emitting assembly is twice a number of types of the plurality of types of laser chips, and a number of groups of the plurality of groups of first pads is greater than the number of types of the plurality of types of laser chips.

4. The light-emitting device according to claim 1, wherein the conductive structure includes a plurality of second pads, and the plurality of second pads are disposed corresponding to the side wall of the at least one package; the conductive portion includes a plurality of third pads, the plurality of third pads correspond to and are welded to the plurality of second pads, respectively, and the plurality of second pads are electrically connected to the connection wires.

5. The light-emitting device according to claim 1, wherein any one type of the plurality of types of laser chips includes one or more laser chips, and the one or more laser chips emit laser beams of the same color; the plurality of types of laser chips include a first-type laser chip, a second-type laser chip, and a third-type laser chip, and the first-type laser chip, the second-type laser chip, and the third-type laser chip emit laser beams of different colors.

6. The light-emitting device according to claim 5, wherein a wavelength of the laser beam emitted by the third-type laser chip is greater than wavelengths of the laser beams emitted by the first-type laser chip and the second-type laser chip.

7. The light-emitting device according to claim 5, wherein the light-emitting device satisfies one of the following:
the at least one package includes a first package and a second package arranged side by side, the third-type laser chip is disposed in the first package, and the first-type laser chip and the second-type laser chip are disposed in the second package;
the at least one package includes three packages arranged in a length direction of the substrate, the first-type laser chip, the second-type laser chip, and the third-type laser chip are disposed in the three packages, respectively; and
the at least one package includes a package, and the first-type laser chip, the second-type laser chip and the third-type laser chip are disposed in the package.

8. The light-emitting device according to claim 1, wherein the at least one package includes a plurality of packages, and any one of the plurality of packages is provided with at least one type of laser chip of the plurality of types of laser chips.

9. The light-emitting device according to claim 8, wherein an arrangement direction of the plurality of packages is the same as an arrangement direction of the plurality of groups of first pads.

10. The light-emitting device according to claim 1, wherein the side wall of the at least one package is made of ceramic, and the bottom wall of the at least one package is made of metal.

11. The light-emitting device according to claim 1, further comprising a temperature-measuring component, wherein the plurality of interconnection regions include a plurality of connection traces, the plurality of connection traces are disposed inside the substrate body, and the temperature-measuring component is connected to a group of the plurality of groups of first pads through at least two of the plurality of connection traces.

12. The light-emitting device according to claim 11, wherein two first pads of the plurality of groups of first pads connected to the temperature-measuring component are located on two sides of a plurality of first pads of the plurality of groups of first pads electrically connected to the plurality of types of laser chips, respectively.

13. The light-emitting device according to claim 11, wherein the temperature-measuring component satisfies at least one of the following:
the temperature-measuring component is located in a middle region of an arrangement direction of the plurality of groups of first pads; and
the plurality of groups of first pads are symmetrically arranged on two sides of the temperature-measuring component.

14. The light-emitting device according to claim 1, wherein the plurality of groups of first pads satisfy at least one of the following:
on a plane where the substrate is located, the plurality of groups of first pads are located on a same side of the at least one package and proximate to an edge of the substrate body;
first pads of a same polarity of the plurality of groups of first pads are arranged adjacently; and
first pads of different polarities of the any group of first pads are arranged adjacent to each other.

15. The light-emitting device according to claim 1, wherein, on a plane where the substrate is located, a single-side width of any one first pad of the plurality of groups of first pads is any value within a range of 1.3 mm to 1.7 mm, inclusive; and in an arrangement direction of the plurality of groups of first pads, a distance between any two adjacent first pads of the plurality of groups of first pads is any value within a range of 0.8 mm to 1.2 mm, inclusive.

16. The light-emitting device according to claim 1, wherein any one first pad of the plurality of groups of first pads includes a metal layer and has a rectangular shape.

17. The light-emitting device according to claim 1, wherein
the at least one connection pattern further includes at least one fixing portion, the at least one fixing portion is disposed on the substrate body and disposed corresponding to the bottom wall of the at least one package, and the light-emitting assembly is disposed on the at least one fixing portion; and
the light-emitting assembly further includes at least one metal film, the at least one metal film is disposed on the side of the at least one package facing the substrate body, and the at least one metal film is connected to the at least one fixing portion, respectively.

18. The light-emitting device according to claim 1, further comprising an electrical coupling component, wherein the electrical coupling component is disposed within a region of the substrate body proximate to the plurality of groups of first pads, the electrical coupling component is electrically connected to the plurality of groups of first pads, and the electrical coupling component is configured to connect to an external electrical signal source.

19. The light-emitting device according to claim 1, wherein the light-emitting assembly further includes at least one cover plate, the at least one cover plate is disposed on a side of the at least one package away from the substrate, any one of the at least one package and any one of the at least one cover plate constitute an accommodating space, and at least one type of the plurality of type of laser chips is accommodated in the accommodating space.

20. A laser projection apparatus, comprising:
a laser source assembly, configured to emit illumination beams, the laser source assembly including the light-emitting device according to claim 1;
a light modulation assembly, configured to modulate the illumination beams provided by the laser source assembly, so as to obtain projection beams; and
a projection lens, configured to project the projection beams into an image.
